(19) United States
(12) Patent Application Publication
(10) Pub. No.: US 2025/0393393 A1
(43) Pub. Date: Dec. 25, 2025

(54) MASK, DISPLAY DEVICE AND METHOD OF MANUFACTURING DISPLAY DEVICE

(71) Applicant: Samsung Display Co., Ltd., Yongin-si (KR)

(72) Inventors: Myung Ji KIM, Yongin-si (KR); Hyo Sung KIM, Yongin-si (KR); Jae Heung PARK, Yongin-si (KR); Ki Young YEON, Yongin-si (KR); Jae Bum HAN, Yongin-si (KR)

(21) Appl. No.: 19/227,285

(22) Filed: Jun. 3, 2025

(30) Foreign Application Priority Data
Jun. 19, 2024 (KR) 10-2024-0079785

(51) Int. Cl. H10K 59/12; C23C 16/04; C23C 16/40; C23C 16/455; H10K 59/80

(52) U.S. Cl. CPC H10K 59/1201; C23C 16/042; C23C 16/403; C23C 16/45525; H10K 59/873

(57) ABSTRACT

A method of manufacturing a display device is provided. The method includes: placing a mask on a base substrate, the base substrate including a base panel having a display area and a pad portion on a side of the display area and in which a pad is located; and depositing an inorganic insulating film on the base panel, wherein the mask includes a frame including ribs defining an opening; and a coating layer on the frame, and wherein the placing of the mask includes placing the mask so that the opening of the mask overlaps the base panel in a plan view and the coating layer overlaps the pad portion in a plan view.

### CROSS-REFERENCE TO RELATED APPLICATION

The present application claims priority to and the benefit of Korean Patent Application No. 10-2024-0079785, filed on Jun. 19, 2024, in the Korean Intellectual Property Office, the entire disclosure of which is incorporated herein by reference.

### BACKGROUND

### 1. Field

Embodiments of the present disclosure relate to a mask, a display device, and a method of manufacturing the display device.

### 2. Description of the Related Art

As information technology advances (develops), the significance (importance) of display devices, which serves as the interface (e.g., which is a connection medium) between users and information, has been highlighted. Accordingly, research and development on display devices are continuously being conducted.

A display device may include a display panel including pixels and a pixel circuit layer for providing a driving signal to the display panel. When a driving voltage of the display device increases, reliability of the display device may decrease.

The information disclosed in this Background section is intended to enhance understanding of the background of the disclosure and may contain information that does not constitute prior art.

### SUMMARY

Aspects of one or more embodiments of the present disclosure relate to a display device with improved reliability and a method of manufacturing the display device.

Aspects of one or more embodiments of the present disclosure relate to a mask that may improve the reliability of a display device.

Additional aspects will be set forth in part in the description which follows and, in part, will be apparent from the description, or may be learned by practice of the presented embodiments of the disclosure.

One or more embodiments of the present disclosure provide a method of manufacturing a display device including: disposing (e.g., placing) a mask on a base substrate including a base panel having a display area and a pad portion on a side of the display area and in which a pad is arranged (e.g., located); and depositing an inorganic insulating film on the base panel, wherein the mask includes a frame including ribs defining an opening; and a coating layer arranged on the frame, and the disposing (e.g., placing) of the mask includes disposing (e.g., placing the mask so that the opening of the mask overlaps the base panel in a plan view and the coating layer overlaps the pad portion in a plan view.

In one or more embodiments, the coating layer may cover a portion of the opening.

In one or more embodiments, the opening may have a first portion that does not overlap the coating layer in a plan view, and a second portion that overlaps the coating layer in a plan view, and the depositing of the inorganic insulating film may include depositing the inorganic insulating film through the first portion.

In one or more embodiments, the depositing of the inorganic insulating film may not deposit the inorganic insulating film in an area overlapping the second portion in a plan view.

In one or more embodiments, the depositing of the inorganic insulating film includes depositing the inorganic insulating film so that the inorganic insulating film does not contact an upper surface of the pad.

In one or more embodiments, the ribs may define a plurality of openings, the plurality of openings including the opening, the base substrate may include a plurality 1 of base panels, the plurality of base panels including the base panel, and each of the openings may overlap each of the base panels in a plan view.

In one or more embodiments, each of the base panels includes a display area and a pad portion on the side of the display area and in which a pad is located; and coating layer may cross each of the plurality of openings, and may overlap each of the pad portions of the plurality of base panels in a plan view.

In one or more embodiments, each of the ribs, the frame, and the coating layer may include at least one of a metal, a polymer, a carbon fiber reinforced plastic (CFRP), and/or a ceramic.

In one or more embodiments, the method further including forming the coating layer through a coating process.

In one or more embodiments, the base substrate may include a silicon wafer substrate for manufacturing an OLED on silicon (OLEDoS) display device.

In one or more embodiments, the base panel may include a light-emitting element layer including a light-emitting element, and the depositing of the inorganic insulating film may include forming an encapsulation layer on the light-emitting element layer so that the encapsulation layer is not in contact with the pad.

One or more embodiments of the present disclosure provide a mask including: a frame including ribs defining openings, the openings each having a first portion and a second portion; and a coating layer arranged on the frame, and wherein the coating layer crosses the openings, and overlaps the first portion of each of the openings in a plan view.

In one or more embodiments, each of the ribs, the frame, and the coating layer may include at least one of a metal, a polymer, a carbon fiber reinforced plastic (CFRP), and/or a ceramic.

In one or more embodiments, the coating layer may not overlap the second portion of each of the openings in a plan view.

In one or more embodiments, the coating layer may be formed through a coating process.

One or more embodiments of the present disclosure provide an electronic device including: a display device including: a substrate having a display area and a non-display area around the display area, the non-display area including a pad portion in which a pad is arranged (e.g., located); a light-emitting element layer on the substrate and including a light-emitting element; and an encapsulation layer covering the light-emitting element layer, wherein the encapsulation layer does not overlap the pad portion in a plan view.

In one or more embodiments, the encapsulation layer may not be in contact with the pad.

In one or more embodiments, the encapsulation layer may further include an inorganic insulating film arranged on the substrate, and the inorganic insulating film may not contact an upper surface of the pad.

According to one or more embodiments of the present disclosure, a display device with improved reliability and a method of manufacturing the display device may be provided.

According to one or more embodiments of the present disclosure, a mask that may improve the reliability of a display device may be provided.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a schematic block diagram of a display device according to one or more embodiments of the present disclosure.

FIG. 2 is a schematic block diagram of one of sub-pixels of FIG. 1 according to one or more embodiments of the present disclosure.

FIG. 3 is a schematic top plan view of a display panel of FIG. 1, according to one or more embodiments of the present disclosure.

FIG. 4 is a schematic exploded perspective view of a portion of a display panel of FIG. 3, according to one or more embodiments of the present disclosure.

FIG. 5 is a schematic top plan view of one of pixels of FIG. 4 according to one or more embodiments of the present disclosure.

FIG. 6 is a schematic cross-sectional view taken along the line I-I′ of FIG. 5, according to one or more embodiments of the present disclosure.

FIG. 7 is a schematic cross-sectional view taken along the line I-I′ of FIG. 5, according to one or more embodiments of the present disclosure.

FIG. 8 is a schematic enlarged view of area “A” of FIG. 7, according to one or more embodiments of the present disclosure.

FIG. 9 is a schematic cross-sectional view of a non-display area of a display device, according to one or more embodiments of the present disclosure.

FIG. 10 is a schematic cross-sectional view of a portion of a light-emitting structure included in one of first to third light-emitting elements of FIG. 6 or FIG. 7, according to one or more embodiments of the present disclosure.

FIG. 11 is a schematic cross-sectional view of a portion of a light-emitting structure included in one of first to third light-emitting elements of FIG. 6 or FIG. 7, according to one or more embodiments of the present disclosure.

FIG. 12 is a schematic top plan view of a pixel, according to one or more embodiments of the present disclosure.

FIG. 13 is a schematic top plan view of a pixel, according to one or more embodiments of the present disclosure.

FIG. 14 is a flowchart of a method of manufacturing a display device according to one or more embodiments of the present disclosure.

FIG. 15 is a schematic top plan view of a base substrate according to one or more embodiments of the present disclosure.

FIG. 16 is a schematic top plan view of a mask according to one or more embodiments of the present disclosure.

FIG. 17 is a schematic cross-sectional view taken along the line A-A′ of FIG. 16, according to one or more embodiments of the present disclosure.

FIG. 18 is a cross-sectional view of process steps of a method of manufacturing a display device according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

The terminology used herein is for the purpose of describing particular embodiments only and is not intended to be limiting of the present disclosure. It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof. As used herein, the term “and/or” includes any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Various embodiments are described herein with reference to sectional illustrations that are schematic illustrations of idealized embodiments. As such, variations from the shapes of the illustrations as a result of, for example, manufacturing techniques and/or tolerances, are to be expected. Thus, example embodiments disclosed herein should not be construed as limited to the particular illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

Unless otherwise noted, like reference numerals denote like elements throughout the attached drawings and the written description, and thus, duplicative descriptions thereof may not be provided. As used herein, the singular forms “a,” “an” and “the” are intended to include the plural forms as well, unless the context clearly indicates otherwise. As used herein, the terms “use,” “using,” and “used” may be considered synonymous with the terms “utilize,” “utilizing,” and “utilized,” respectively.

The present disclosure relates to a mask, a display device, and a method of manufacturing the display device. The mask of the present disclosure may be a deposition mask used if (e.g., when) manufacturing a display device. Hereinafter, a mask, a display device, and a method of manufacturing the display device according to one or more embodiments will be described with reference to the accompanying drawings.

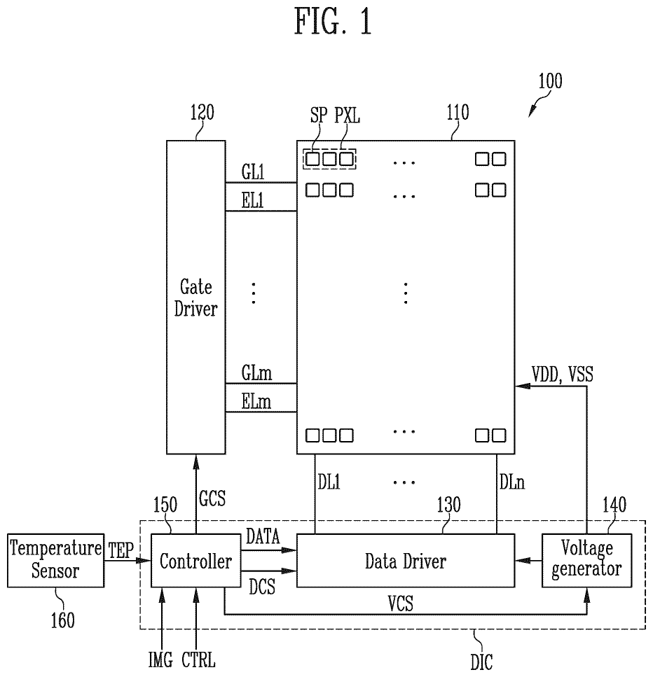

FIG. 1 is a schematic block diagram of a display device according to one or more embodiments of the present disclosure.

Referring to FIG. 1, the display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light-emitting element configured to generate and/or to emit light. Accordingly, the sub-pixels SP may respectively be to emit light of a specific color, such as red, green, blue, cyan, magenta, yellow, and/or the like. Two or more of the sub-pixels SP may constitute one pixel PXL. For example, as shown in FIG. 1, three sub-pixels may constitute one pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In one or more embodiments, the gate control signal GCS may include a start signal indicating the start of each frame, a horizontal synchronization signal for outputting gate signals in synchronization with the timing at which data signals are applied, and/or the like.

In one or more embodiments, first to m-th light-emitting control lines EL1 to ELm connected to the sub-pixels SP in the row direction may be further provided. In such embodiments, the gate driver 120 may include a light-emitting control driver configured to control the first to m-th light-emitting control lines EL1 to ELm, and the light-emitting control driver may operate under the control of the controller 150.

The gate driver 120 may be arranged on a (e.g., one side) of the display panel 110. However, the present disclosure is not limited thereto. For example, the gate driver 120 may be divided into two or more physically and/or logically separated drivers, and the drivers may be arranged on one side of the display panel 110 and on the other side of the display panel 110 opposite to the one side. As described above, the gate driver 120 may be arranged around the display panel 110 in one or more suitable forms according to one or more embodiments.

The data driver 130 may be connected to the sub-pixels SP arranged in a column direction through the first to n-th data lines DL1 to DLn. The data driver 130 may receive image data (DATA) and data control signal DCS from the controller 150. The data driver 130 may operate in response to the data control signal DCS. In one or more embodiments, the data control signal DCS may include a source start pulse, a source shift clock, a source output enable signal, and/or the like.

The data driver 130 may use voltages from the voltage generator 140 to apply data signals having grayscale voltages corresponding to the image data (DATA) to the first to n-th data lines DL1 to DLn. When a gate signal is applied to each of the first to m-th gate lines GL1 to GLm, data signals corresponding to the image data DATA may be applied to the data lines DL1 to DLm. Accordingly, the corresponding sub-pixels SP may be to emit light corresponding to the data signals. Accordingly, an image may be displayed on the display panel 110.

In one or more embodiments, the gate driver 120 and the data driver 130 may each include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to constituent elements of the display device 100. For example, the voltage generator 140 may be configured to generate a plurality of voltages by receiving an input voltage from outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the first power voltage VDD. In one or more embodiments, the first power voltage VDD or the second power voltage VSS may be provided by an external device of the display device 100.

In one or more embodiments, the voltage generator 140 may generate one or more suitable voltages. For example, the voltage generator 140 may generate an initialization voltage applied to the sub-pixels SP. For example, during a sensing operation to sense electrical characteristics of transistors and/or light-emitting elements of the sub-pixels SP, a set or predetermined reference voltage may be applied to the first to n-th data lines DL1 to DLn, and the voltage generator 140 may generate the reference voltage.

The controller 150 may control one or more suitable operations of the display device 100. The controller 150 may receive input image data IMG and a control signal CTRL for controlling the display of the input image data from the outside. The controller 150 may provide the gate control signal GCS, the data control signal DCS, and the voltage control signal VCS in response to the control signal CTRL.

The controller 150 may convert the input image data IMG to be suitable for the display device 100 or the display panel 110 to output the image data DATA. In one or more embodiments, the controller 150 may output the image data DATA by aligning the input image data IMG to be suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In such embodiments, the data driver 130, the voltage generator 140, and the controller 150 may be functionally separate components within one driver integrated circuit DIC. However, the present disclosure is not necessarily limited thereto. In one or more embodiments, at least one of the data driver 130, the voltage generator 140, and the controller 150 may be provided as a component separated from the driver integrated circuit DIC.

The display device 100 may include at least one temperature sensor 160. The temperature sensor 160 is configured to sense a surrounding temperature and generate temperature data TEP representing the sensed temperature. In one or more embodiments, the temperature sensor 160 may be arranged to be adjacent to the display panel 110 and/or the driver integrated circuit DIC.

The controller 150 may control one or more suitable operations of the display device 100 in response to the temperature data TEP. In one or more embodiments, the controller 150 may control and/or adjust the luminance of an image outputted from the display panel 110 in response to the temperature data TEP. For example, the controller 150 may control the data signals and the first and second power voltages VDD and VSS by controlling components such as the data driver 130 and/or the voltage generator 140.

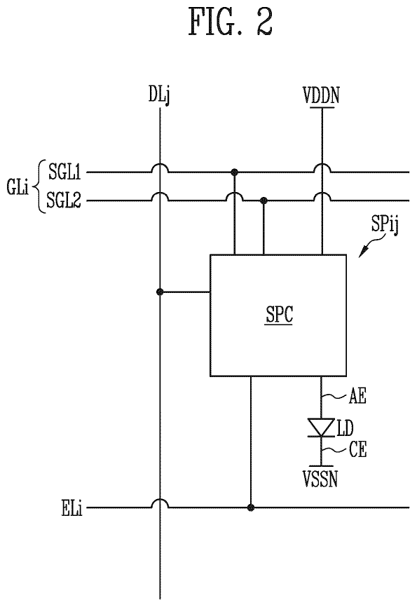

FIG. 2 is a schematic block diagram of one of the sub-pixels of FIG. 1 according to one or more embodiments of the present disclosure. In FIG. 2, among the sub-pixels SP of FIG. 1, a sub-pixel SPij arranged in an i-th row (i is an integer greater than or equal to 1 and less than or equal to m) and a j-th column (j is an integer greater than or equal to 1 and less than or equal to n) is illustrated as an example.

Referring to FIG. 2, the sub-pixel SPij may include a sub-pixel circuit SPC and a light-emitting element LD.

The light-emitting element LD may be connected between the first power voltage node VDDN and a second power voltage node VSSN. In such embodiments, the first power voltage node VDDN is a node that transmits the first power voltage VDD of FIG. 1, and the second power voltage node VSSN is a node that transmits the second power voltage VSS of FIG. 1.

An anode electrode AE of the light-emitting element LD may be connected to the first power voltage node VDDN through the sub-pixel circuit SPC, and a cathode electrode CE of the light-emitting element LD may be connected to the second power voltage node VSSN. For example, the anode electrode AE of the light-emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th light-emitting control line ELi among the first to m-th light-emitting control lines EL1 to ELm of FIG. 1, and a j-th data line DLj among the first to n-th data lines DL1 to DLn of FIG. 1. The sub-pixel circuit SPC may be configured to control the light-emitting element LD according to signals received through these signal lines.

The sub-pixel circuit SPC may operate in response to a gate signal received through the i-th gate line GLi. The i-th gate line GLi may include one or more sub-gate lines. In one or more embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As such, if (e.g., when) the i-th gate line GLi includes two or more sub-gate lines, the sub-pixel circuit SPC may operate in response to gate signals received through the corresponding sub-gate lines.

The sub-pixel circuit SPC may operate in response to a light-emitting control signal received through the i-th light-emitting control line ELi. In one or more embodiments, the i-th light-emitting control line ELi may include one or more sub-light-emitting control lines. When the i-th light-emitting control line ELi includes two or more sub-light-emitting control lines, the sub-pixel circuit SPC may operate in response to light-emitting control signals received through the corresponding sub-light-emitting control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. In response to the light-emitting control signal received through the i-th light-emitting control line ELi, the sub-pixel circuit SPC may adjust the current flowing from the first power voltage node VDDN to the second power voltage node VSSN through the light-emitting element LD according to the stored voltage. Accordingly, the light-emitting element LD may generate and/or emit light with a brightness (luminance) corresponding to the data signal.

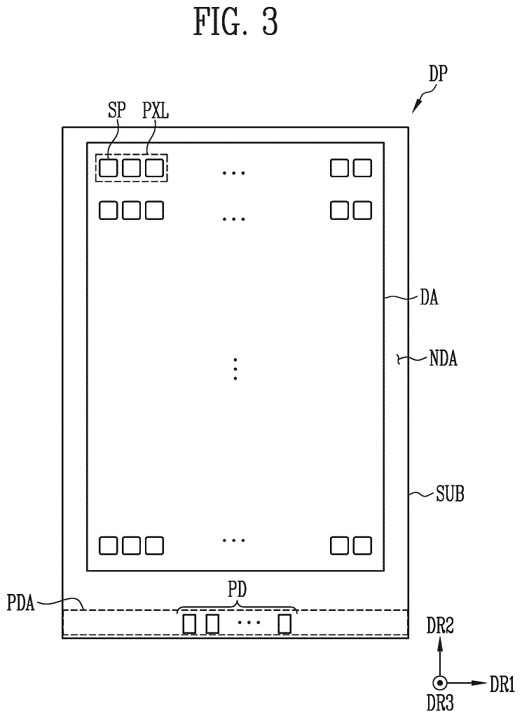

FIG. 3 is a schematic top plan view of a display panel of FIG. 1 according to one or more embodiments of the present disclosure.

Referring to FIG. 3, one or more embodiments of the display panel DP of FIG. 1 may include a display area DA and a non-display area NDA. The display panel DP may display images through the display area DA. The non-display area NDA is arranged around the display area DA.

The display panel DP may include a substrate SUB, sub-pixels SP, and a pad PD. In one or more embodiments, a plurality of pads PD may be provided. For example, the display panel DP may include pads PD.

When the display panel DP may be used as a display screen for a head mounted display (HMD), a virtual reality (VR) device, a mixed reality (MR) device, or an augmented reality (AR) device, the display panel DP may be positioned very close to the user's eyes. In such embodiments, sub-pixels SP with relatively high integration may be use. In order to increase the integration of the sub-pixels SP, the substrate SUB may be provided as a silicon substrate. The sub-pixels SP and/or the display panel DP may be formed on the substrate SUB, which is a silicon substrate. The display device 100 (see, e.g., FIG. 1) including the display panel DP formed on the substrate SUB, which is a silicon substrate, may be referred to as an OLED on silicon (OLEDoS) display device. For example, an electronic device including a display device may include various forms such as a head-mounted display (HMD), a virtual reality (VR) device, a mixed reality (MR) device, or an augmented reality (AR) device. These devices utilize the high integration of sub-pixels SP on a silicon substrate to provide high-resolution displays positioned close to the user's eyes, enhancing the immersive experience. The use of a silicon substrate allows for the formation of highly integrated sub-pixels SP, which may be essential for the compact and high-performance display requirements of these electronic devices.

The sub-pixels SP are arranged in the display area DA on the substrate SUB. The sub-pixels SP may be arranged in a matrix format along a first direction DR1 and a second direction DR2 that intersects the first direction DR1. However, the present disclosure is not limited thereto. For example, the sub-pixels SP may be arranged in a zigzag form along first direction DR1 and second direction DR2. For example, the sub-pixels SP may be arranged in a PENTILE™ shape (for example, an RGBG matrix or an RGBG structure). PENTILE® is a duly registered trademark of Samsung Display Co. The first direction DR1 may be a row direction, and the second direction DR2 may be a column direction. In one or more embodiments, a third direction DR3 may be a direction normal (e.g., perpendicular) to the first direction DR1 and the second direction DR2, and may be a normal direction of a plane on which the display panel DP is arranged.

Two or more of the plurality of sub-pixels SP may constitute a (e.g., one) pixel PXL. In other words, a pixel PXL may include one or more sub-pixels SP, such as two or more sub-pixels SP.

Constituent elements (e.g., components) to control the sub-pixels SP may be arranged in the non-display area NDA on the substrate SUB. For example, wires connected to the sub-pixels SP, such as the first to m-th gate lines GL1 to GLm and the first to n-th data lines DL1 to DLn of FIG. 1, may be arranged in the non-display area NDA.

At least one of the gate driver 120, the data driver 130, the voltage generator 140, the controller 150, and/or the temperature sensor 160 in FIG. 1 may be integrated in the non-display area NDA of the display panel DP. In one or more embodiments, the gate driver 120 of FIG. 1 may be mounted on the display panel DP, and may be arranged in the non-display area NDA. However, the present disclosure is not necessarily limited thereto. In one or more embodiments, the gate driver 120 may be implemented as an integrated circuit separate from the display panel DP. In one or more embodiments, the temperature sensor 160 may be arranged in the non-display area NDA to detect the temperature of the display panel DP.

The pads PD may be arranged in the non-display area NDA on the substrate SUB. The non-display area NDA may include a pad portion PDA in which the pads PD are arranged. The pad portion PDA may overlap the pads PD in a plan view. The pads PD may be electrically connected to the sub-pixels SP through wires. For example, the pads PD may be connected to the sub-pixels SP through the first to n-th data lines DL1 to DLn.

The pads PD may interface the display panel DP to other constituent elements (components) of the display device 100 (see, e.g., FIG. 1). In one or more embodiments, voltages and signals for the operation of constituent elements included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, if (e.g., when) the gate driver 120 is mounted on the display panel DP, the gate control signal GCS may be transmitted from the driver integrated circuit DIC to the gate driver 120 through the pads PD.

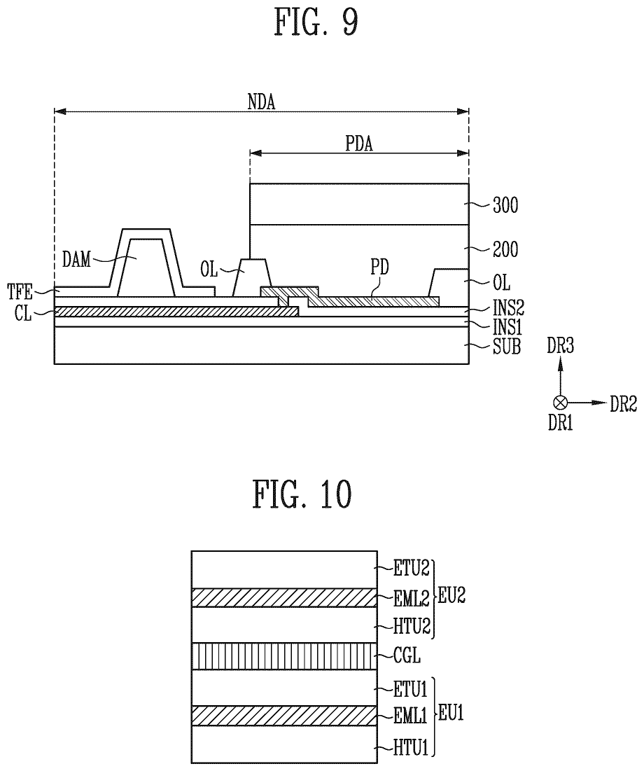

In one or more embodiments, a circuit board 300 (see, e.g., FIG. 9) may be electrically connected to the pads PD using a conductive adhesive member 200 (see, e.g., FIG. 9), such as an anisotropic conductive film. In such embodiments, the circuit board 300 may be a flexible printed circuit board (FPCB) or a flexible film made of a flexible material. The driver integrated circuit DIC may be mounted on the circuit board to be electrically connected to the pads PD.

In one or more embodiments, the display area DA may have one or more suitable shapes. The display area DA may have a closed-loop shape including straight and/or curved edges. For example, the display area DA may have shapes such as a polygonal shape, a circular shape, a semicircular, and/or an elliptical shape.

In one or more embodiments, the display panel DP may have a flat display surface. However, the present disclosure is not necessarily limited thereto. In one or more embodiments, the display panel DP may have a display surface that is at least partially rounded. In one or more embodiments, the display panel DP may be bendable, foldable, and/or rollable. In such embodiments, the display panel DP and/or the substrate SUB may include flexible materials.

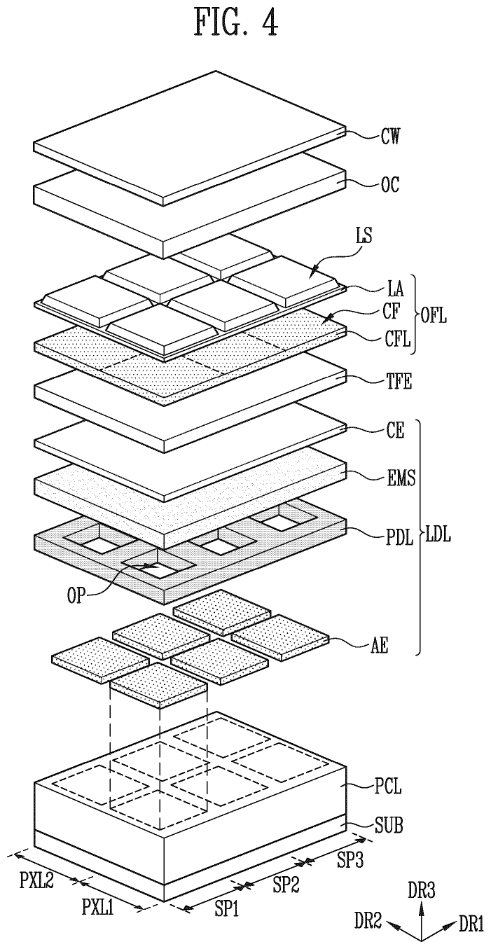

FIG. 4 is a schematic exploded perspective view of a portion of the display panel of FIG. 3, according to one or more embodiments of the present disclosure. In FIG. 4, for clear and concise description, the portion of the display panel DP corresponding to two pixels PXL1 and PXL2 among the pixels PXL of FIG. 4 are schematically shown. Portions of the display panel DP corresponding to the remaining pixels may be similarly configured.

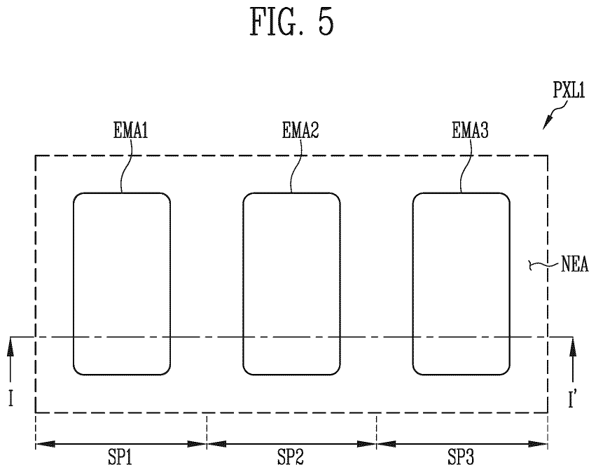

Referring to FIG. 4 and FIG. 5, each of the first and second pixels PXL1 and PXL2 may include first to third sub-pixels SP1, SP2, and SP3. However, the present disclosure is not limited thereto. For example, each of the first and second pixels PXL1 and PXL2 may include four sub-pixels, or two sub-pixels.

In FIG. 4, the first to third sub-pixels SP1, SP2, and SP3 are shown to have quadrangular shapes and have the same sizes if (e.g., when) viewed in the third direction DR3 crossing the first and second directions DR1 and DR2. However, the present disclosure is not limited thereto. The first to third sub-pixels SP1, SP2, and SP3 may be modified to have one or more suitable shapes.

The display panel DP may include a substrate SUB, a pixel circuit layer PCL, a light-emitting element layer LDL, an encapsulation layer TFE, an optical functional layer OFL, an overcoat layer OC, and a cover window CW.

In one or more embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, an epitaxial layer, a silicon on Insulator (SOI) layer, or a semiconductor on insulator (SeOI) layer. In one or more embodiments, the substrate SUB may include a glass substrate. In still one or more embodiments, the substrate SUB may include a polyimide (PI) substrate.

The pixel circuit layer PCL is arranged on the substrate SUB. The substrate SUB and/or the pixel circuit layer PCL may include insulating layers and conductive patterns arranged between the insulating layers. The conductive patterns of the pixel circuit layer PCL may function as at least a part of circuit elements, wires, and/or the like.

The conductive patterns may include copper, but the present disclosure is not limited thereto.

The circuit elements may include a sub-pixel circuit SPC (see, e.g., FIG. 2) for each of first to third sub-pixels SP1, SP2, and SP3. The sub-pixel circuit SPC may include transistors and one or more capacitors. Each transistor may include a semiconductor portion including a source region, a drain region, and a channel region, and a gate electrode overlapping the semiconductor portion. In one or more embodiments, if (e.g., when) the substrate SUB is provided as a silicon substrate, the semiconductor portion may be included in the substrate SUB, and the gate electrode may be included in the pixel circuit layer PCL as the conductive pattern of the pixel circuit layer PCL. In one or more embodiments, if (e.g., when) the substrate SUB is provided as a glass substrate or a PI substrate, the semiconductor portion and the gate electrode may be included in the pixel circuit layer PCL. Each capacitor may include electrodes spaced and/or apart (e.g., spaced apart or separated) from each other. For example, each capacitor may include electrodes spaced and/or apart (e.g., spaced apart or separated) from each other on a plane (e.g., in a plan view) defined by the first and second directions DR1 and DR2. For example, each capacitor may include electrodes spaced and/or apart (e.g., spaced apart or separated) from each other in the third direction DR3 with an insulating layer therebetween. In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the direction DR3 refers to a top-down view of the display panel, as if looking directly down onto the surface from above. In this context, DR3 is the direction perpendicular or normal to the plane defined by the first direction (DR1) and the second direction (DR2). This refers to that in a plan view, the arrangement of sub-pixels, pads, and other components as they are laid out on the substrate can be seen, without any perspective distortion.

The wires of the pixel circuit layer PCL may include signal lines connected to each of the first to third sub-pixels SP1, SP2, and SP3 for example, a gate line, a light-emitting control line, and a data line. The wires may further include the wire connected to the first power voltage node VDDN of FIG. 2. In one or more embodiments, the wires may further include the wire connected to the second power voltage node VSSN of FIG. 2.

The light-emitting element layer LDL may include anode electrodes AE, a pixel-defining layer PDL, a light-emitting structure EMS, and a cathode electrode CE.

The anode electrodes AE may be arranged on the pixel circuit layer PCL. The anode electrodes AE may contact circuit elements of the pixel circuit layer PCL. The anode electrodes AE may include an opaque conductive material capable of reflecting light, but the present disclosure is not limited thereto.

The pixel-defining layer PDL is arranged on the anode electrodes AE. The pixel-defining layer PDL may include an opening OP (e.g., openings OP) exposing a portion of each of the anode electrodes AE. The opening OP of the pixel-defining layer PDL may be defined as light-emitting areas respectively corresponding to the first to third sub-pixels SP1 to SP3. In one or more embodiments, it may be understood that light-emitting areas respectively corresponding to the first to third sub-pixels SP1 to SP3 are defined according to the anode electrodes AE. In areas adjacent to the boundaries of neighboring sub-pixels, the pixel-defining layer PDL may include separators causing a discontinuity to be formed within the light-emitting structure EMS. In such embodiments, it may be understood that light-emitting areas respectively corresponding to the first to third sub-pixels SP1 to SP3 are defined according to the separators of the pixel-defining layer PDL.

In one or more embodiments, the pixel-defining layer PDL may include an inorganic material. In such embodiments, the pixel-defining layer PDL may include a plurality of stacked inorganic layers. For example, the pixel-defining layer PDL may include a silicon oxide (SiOₓ, where 0<x≤2, e.g., SiO₂) and a silicon nitride (SiₓN_{y}, where 0<x≤3 and 0<y≤4, e.g., Si₃N₄). In one or more embodiments, the pixel-defining layer PDL may include an organic material. However, the material of the pixel-defining layer PDL is not limited thereto.

The light-emitting structure EMS may be arranged on the anode electrodes AE exposed by the opening OP of the pixel-defining layer PDL. The light-emitting structure EMS may include a light-emitting layer configured to generate and/or emit light, an electron transport layer configured to transport electrons, and a hole transport layer configured to transport holes.

In one or more embodiments, the light-emitting structure EMS may fill the opening OP of the pixel-defining layer PDL, and may be arranged entirely on an upper portion of the pixel-defining layer PDL. For example, the light-emitting structure EMS may extend across the first to third sub-pixels SP1 to SP3. In such embodiments, at least some of the functional layers in the light-emitting structure EMS may be disconnected and/or bent at the boundaries between the first to third sub-pixels SP1 to SP3. However, the present disclosure is not limited thereto. For example, portions of the light-emitting structure EMS corresponding to the first to third sub-pixels SP1 to SP3 are separated from each other, and each of them may be arranged in the opening OP of the pixel-defining layer PDL.

The cathode electrode CE may be arranged on the light-emitting structure EMS. The cathode electrode CE may extend across the first to third sub-pixels SP1 to SP3. As such, the cathode electrode CE may be provided as a common electrode for the first to third sub-pixels SP1 to SP3.

The cathode electrode CE may be a thin metal layer with a thickness sufficient to transmit light emitted from the light-emitting structure EMS. The cathode electrode CE may be made of a metallic material or a transparent conductive material to have a relatively thin thickness. In one or more embodiments, the cathode electrode CE may include at least one of one or more suitable transparent conductive materials including an indium tin oxide, an indium zinc oxide, an indium tin zinc oxide, an aluminum zinc oxide, a gallium zinc oxide, a zinc tin oxide, and/or a gallium tin oxide. In one or more embodiments, the cathode electrode CE may include at least one of silver (Ag), magnesium (Mg), and/or a (e.g., any suitable) mixture thereof. However, the material of the cathode electrode CE is not limited thereto.

One of the anode electrodes AE, the portion of the light-emitting structure EMS overlapping it, and the portion of the cathode electrode CE overlapping it, may be understood to constitute one light-emitting element LD (see, e.g., FIG. 2). For example, each of the light-emitting elements of the first to third sub-pixels SP1 to SP3 may include one anode electrode, a portion of the light-emitting structure EMS overlapping it, and a portion of the cathode electrode CE overlapping it. In each of the first to third sub-pixels SP1 to SP3, holes injected from the anode electrode AE and electrons injected from the cathode electrode CE are transported into the light-emitting layer of the light-emitting structure EMS to form excitons, and if (e.g., when) the excitons transition from the excited state to the ground state, light may be generated and/or emitted. The luminance (brightness) of light may be determined depending on the amount of current flowing through the light-emitting layer. Depending on the configuration of the light-emitting layer, the wavelength range of the generated light may be determined.

The encapsulation layer TFE is arranged on the cathode electrode CE. The encapsulation layer TFE may cover the light-emitting element layer LDL and/or the pixel circuit layer PCL. The encapsulation layer TFE may be configured to prevent or reduce the likelihood of oxygen and/or moisture penetrating into the light-emitting element layer LDL. In one or more embodiments, the encapsulation layer TFE may include a structure in which one or more inorganic films and one or more organic films are alternately stacked. For example, the inorganic film may include a silicon nitride, a silicon oxide, or a silicon oxynitride (SiOₓN_{y}. e.g., the range for x may be from 0 to 2, and the range for y may be from 0 to 4). For example, the organic film may include an organic insulating material such as an acrylic resin, an epoxy resin, a phenol resin, a 1 polyamide resin, a polyimide resin, an unsaturated polyester resin, a polyphenylene ether resin, a polyphenylene sulfide resin, or a benzocyclobutene. However, the materials of the organic film and the inorganic film of the encapsulation layer TFE are not limited thereto.

The encapsulation layer TFE may further include a thin film containing an aluminum oxide (AlₓO_{y}, e.g., the range for x may be from 0 to 2, and the range for y may be from 0 to 3, e.g., Al₂O₃) in order to improve the encapsulation efficiency of the encapsulation layer TFE. The thin film containing an aluminum oxide may be arranged on the upper surface of the encapsulation layer TFE facing (e.g., opposite to) the optical functional layer OFL and/or on the lower surface of the encapsulation layer TFE facing (e.g., opposite to) the light-emitting element layer LDL.

The thin film containing the aluminum oxide may be formed through atomic layer deposition (ALD). However, the present disclosure is not limited thereto. The encapsulation layer TFE may further include a thin film made of at least one of one or more materials suitable for improving the encapsulation efficiency.

The optical functional layer OFL is arranged on the encapsulation layer TFE. The optical function layer OFL may include a color filter layer CFL and a lens array LA.

The color filter layer CFL may be arranged between the encapsulation layer TFE and the lens array LA. The color filter layer CFL is configured to selectively output light in a wavelength range or color corresponding to each sub-pixel by filtering light emitted from the light-emitting structure EMS. The color filter layer CFL includes color filters CF respectively corresponding to the first to third sub-pixels SP1 to SP3, and each of the color filters CF may be to transmit light in a wavelength range corresponding to the sub-pixel. For example, a color filter corresponding to the first sub-pixel SP1 may be to transmit red light, a color filter corresponding to the second sub-pixel SP2 may be to transmit green light, and a color filter corresponding to the third sub-pixel SP3 may be to transmit blue light. At least some of the color filters CF 1 may not be provided according to light emitted from the light-emitting structure EMS of each sub-pixel.

The lens array LA may be arranged on the color filter layer CFL. The lens array LA may include lenses LS respectively corresponding to the first to third sub-pixels SP1 to SP3. Each of the lenses LS may improve light output efficiency by outputting light emitted from the light-emitting structure EMS in an intended path. The lens array LA may have a relatively high refractive index. For example, the lens array LA may have a higher refractive index than the overcoat layer OC. In one or more embodiments, the lenses LS may include an organic material. In one or more embodiments, the lenses LS may include an acrylic material. However, the material of the lenses LS is not limited thereto.

In one or more embodiments, compared to the opening OP of the pixel-defining layer PDL, at least some of the color filters CF of the color filter layer CF and at least some of the lenses LS of the lens array LA may be shifted in a direction parallel to a plane defined by the first and second directions DR1 and DR2. For example, in the center area of the display area DA, the center of the color filter and the center of the lens may be aligned or may overlap with the center of the opening OP of the corresponding portion of the pixel-defining layer PDL when viewed in the third direction DR3. For example, in the central area of the display area DA, the opening OP of the pixel-defining layer PDL may completely overlap the corresponding color filter of the color filter layer CF and the corresponding lens of the lens array LA. In an area of the display area DA adjacent to the non-display area NDA, the center of the color filter and the center of the lens may be shifted in a planar direction from the center of the opening OP of the corresponding portion of the pixel-defining layer PDL when viewed in the third direction DR3. For example, in an area of the display area DA adjacent to the non-display area NDA, the opening OP of the pixel-defining layer PDL may partially overlap the corresponding color filter of the color filter layer CFL and the corresponding lens of the lens array LA. Accordingly, in the center of the display area DA, light emitted from the light-emitting structure EMS may be efficiently outputted in the normal (e.g., perpendicular) direction of the display surface. Light emitted from the light-emitting structure EMS at the outside of the display area DA may be efficiently outputted in a direction inclined by a set or predetermined angle with respect to the normal (e.g., perpendicular) direction of the display surface.

The overcoat layer OC may be arranged on the lens array LA. The overcoat layer OC may cover the optical functional layer OFL, the encapsulation layer TFE, the light-emitting structure EMS, and/or the pixel circuit layer PCL. The overcoat layer OC may include one or more materials suitable for protecting lower layers thereof from foreign substances such as dust and moisture. For example, the overcoat layer OCL may include at least one of an inorganic insulating film and/or an organic insulating film. For example, the overcoat layer OC may include an epoxy resin, but the present disclosure is not limited thereto. The overcoat layer OC may have a lower refractive index than the lens array LA.

The cover window CW may be arranged on the overcoat layer OC. The cover window CW is configured to protect lower layers thereof. The cover window CW may have a higher refractive index than the overcoat layer OC. The cover window CW may include glass, but the present disclosure is not limited thereto. For example, the cover window CW may be an encapsulation glass configured to protect constituent elements (components) arranged thereunder. In one or more embodiments, the cover window CW may not be provided.

FIG. 5 is a schematic top plan view of one of pixels of FIG. 4 according to one or more embodiments of the present disclosure. For a clear and concise description in FIG. 5, the first pixel PXL1 among the first and second pixels PXL1 and PXL2 of FIG. 4 is schematically illustrated. The remaining pixels may be configured similarly to the first pixel PXL1.

Referring to FIG. 4 and FIG. 5, a first pixel PXL1 may include the first to third sub-pixels SP1 to SP3 arranged in the first direction DR1.

The first sub-pixel SP1 may include a first light-emitting area EMA1 and a non-light emitting area NEA around the first light-emitting area EMA1. The second sub-pixel SP2 may include a second light-emitting area EMA2 and a non-light emitting area NEA around the second light-emitting area EMA2. The third sub-pixel SP3 may include a third light-emitting area EMA3 and a non-light emitting area NEA around the third light-emitting area EMA3.

The first light-emitting area EMA1 may be an area in which light is emitted from a portion of the light-emitting layer EML (see, e.g., FIG. 4) corresponding to the first sub-pixel SP1. The second light-emitting area EMA2 may be an area in which light is emitted from a portion of the light-emitting structure EMS corresponding to the second sub-pixel SP2. The third light-emitting area EMA3 may be an area in which light is emitted from a portion of the light-emitting structure EMS corresponding to the third sub-pixel SP3.

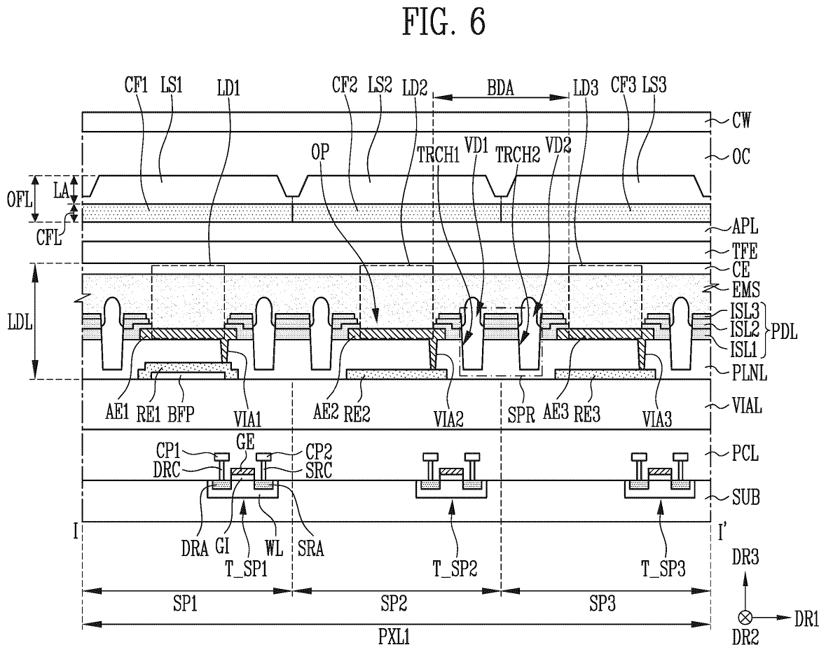

FIG. 6 is a schematic cross-sectional view taken along the line I-I′ of FIG. 5, according to one or more embodiments of the present disclosure. FIG. 6 illustrates a cross-section of the display area DA.

Referring to FIG. 6, the substrate SUB and the pixel circuit layer PCL arranged on the substrate SUB are provided.

The substrate SUB may include a silicon wafer substrate formed using a semiconductor process. For example, the substrate SUB may include silicon, germanium, and/or silicon-germanium.

The pixel circuit layer PCL is arranged on the substrate SUB. The substrate SUB and the pixel circuit layer PCL may include circuit elements for each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (see, e.g., FIG. 2) of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 6, for clear and concise description, one of the transistors of each sub-pixel is shown and the remaining circuit elements may not be provided.

The transistor T_SP1 of the first sub-pixel SP1 may include a source area SRA, a drain area DRA, and a gate electrode GE.

The source area SRA and the drain area DRA may be arranged within the substrate SUB. A well WL formed through an ion injection process is arranged in the substrate SUB, and the source area SRA and the drain area DRA may be arranged to be spaced and/or apart (e.g., spaced apart or separated) from each other within the well WL. The area between the source area SRA and the drain area DRA within the well WL may be defined as a channel area.

The gate electrode GE overlaps the channel area between the source area SRA and the drain area DRA, and may be arranged on the pixel circuit layer PCL. The gate electrode GE may be separated from the well WL or the channel area by an insulating material such as a gate insulating layer GI. The gate electrode GE may include a conductive material.

A plurality of layers included in the pixel circuit layer PCL include insulating layers and conductive patterns arranged between the insulating layers, and the conductive patterns may include first and second conductive patterns CP1 and CP2. The first conductive pattern CP1 may be electrically connected to the drain area DRA through a drain connection portion DRC penetrating one or more insulating layers. The second conductive pattern CP2 may be electrically connected to the source area SRA through a source connection portion SRC penetrating one or more insulating layers.

As the gate electrode GE and the first and second conductive patterns CP1 and CP2 are connected to other circuit elements and/or wires, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1.

As described above, for example, the substrate SUB and the pixel circuit layer PCL may include circuit elements for each of the first to third sub-pixels SP1 to SP3.

A via layer VIAL is arranged on the pixel circuit layer PCL. The via layer VIAL covers the pixel circuit layer PCL, and may have an overall (or entirely) flat surface. The via layer VIAL is configured to flatten steps on the pixel circuit layer PCL. The via layer VIAL may include at least one of a silicon oxide (SiOₓ), a silicon nitride (SiₓN_{y}), and/or a silicon carbon nitride (SiCN), but the present disclosure is not limited thereto.

The light-emitting element layer LDL is arranged on the via layer VIAL. The light-emitting element layer LDL may include first to third reflective electrodes RE1 to RE3, a planarization layer PLNL, first to third anode electrodes AE1 to AE3, a pixel-defining layer PDL, a light-emitting structure EMS, and a cathode electrode CE. The first to third reflective electrodes RE1 to RE3 are arranged in the first to third sub-pixels SP1 to SP3 on the via layer VIAL, respectively. Each of the first to third reflective electrodes RE1 to RE3 may contact a circuit element arranged on (in) the pixel circuit layer PCL through a via penetrating the via layer VIAL.

The first to third reflective electrodes RE1 to RE3 may function as full mirrors that reflect light emitted from the light-emitting structure EMS toward the display surface (or the cover window CW). In the context of the present disclosure, full mirrors are reflective surfaces designed to reflect light or substantially completely, often used to create clear and accurate reflections. For examples, full mirrors are typically made from metallic materials like aluminum, silver, or gold, which have high reflectivity. These mirrors are used to direct light emitted from a light-emitting structure towards the display surface, enhancing the brightness and clarity of the display. The first to third reflective electrodes RE1 to RE3 may include metallic materials suitable for reflecting light. The first to third reflective electrodes RE1 to RE3 may include at least one of aluminum (AI), silver (Ag), magnesium (Mg), platinum (Pt), palladium (Pd), gold (Au), nickel (Ni), neodymium (Nd), iridium (Ir), chromium (Cr), titanium (Ti), and/or an alloy of two or more materials selected therefrom, but the present disclosure is not limited thereto.

In one or more embodiments, a connection electrode may be arranged below each of the first to third reflective electrodes RE1 to RE3. The connection electrodes may improve electrical connection characteristics between each of the reflective electrodes and the corresponding circuit element of the pixel circuit layer PCL. The connection electrodes may each have a multi-layered structure. The multi-layered structure may include titanium (Ti), a titanium nitride (TiN), a tantalum nitride (TaN), and/or the like, but the present disclosure is not limited thereto. In one or more embodiments, a corresponding reflective electrode may be arranged between the multiple layers of the connection electrode.

A buffer pattern BFP may be arranged below at least one of the first to third reflective electrodes RE1 to RE3. The buffer pattern BFP may include an inorganic material such as a silicon carbon nitride, but the present disclosure is not limited thereto. By disposing/arranging the buffer pattern BFP, the height of the corresponding reflective electrode may be adjusted in the third direction DR3. For example, the buffer pattern BFP may be arranged between the first reflective electrode RE1 and the via layer VIAL to adjust the height of the first reflective electrode RE1.

The first to third reflective electrodes RE1 to RE3 may function as full mirrors, and the cathode electrode CE may function as a half mirror. For example, each of the first to third reflection electrodes RE1 to RE3 and the cathode electrode CE may provide a resonance structure in a corresponding sub-pixel. Light emitted from the light-emitting layer of the light-emitting structure EMS may be amplified by reciprocating between the reflective electrode and the cathode electrode CE, and the amplified light may be outputted through the cathode electrode CE. As such, the distance between each reflective electrode and the cathode electrode CE may be understood as the resonance distance for the light emitted from the light-emitting layer of the corresponding light-emitting structure EMS.

The first sub-pixel SP1 may have a shorter resonance distance than other sub-pixels due to the buffer pattern BFP. The resonance distance adjusted in this way may allow light in a specific wavelength range (for example, red color) to be effectively and efficiently amplified. Accordingly, the first sub-pixel SP1 may effectively and efficiently output light in the corresponding wavelength range.

In FIG. 6, the buffer pattern BFP is shown to be provided in the first sub-pixel SP1 and not in the second and third sub-pixels SP2 and SP3, but the present disclosure is not limited thereto. The buffer pattern may be also provided in at least one of the second and/or third sub-pixels SP2 and SP3, so that the resonance distance of at least one of the second and/or third sub-pixels SP2 and SP3 may be adjusted. For example, the first to third sub-pixels SP1 to SP3 may correspond to red, green, and blue, respectively, the distance between the first reflective electrode RE1 and the cathode electrode CE may be shorter than the distance between the second reflective electrode RE2 and the cathode electrode CE, and the distance between the second reflective electrode RE2 and the cathode electrode CE may be shorter than the distance between the third reflective electrode RE3 and the cathode electrode CE.

To planarize the steps between the first to third reflective electrodes RE1 to RE3, the planarization layer PLNL may be arranged on the via layer VIAL and the first to third reflective electrodes RE1 to RE3. The planarization layer PLNL may cover (e.g., entirely cover) the first to third reflective electrodes RE1 to RE3 and the via layer VIAL, and may have a flat surface. In one or more embodiments, the planarization layer PLNL may not be provided.

The first to third anode electrodes AE1 to AE3 may respectively overlap the first to third reflective electrodes RE1 to RE3 that are arranged on the planarization layer PLNL. The first to third anode electrodes AE1 to AE3 may have shapes similar to the first to third light-emitting areas EMA1 to EMA3 of FIG. 6 when viewed in the third direction DR3. The first to third anode electrodes AE1 to AE3 are respectively connected to the first to third reflective electrodes RE1 to RE3. The first anode electrode AE1 may be connected to the first reflective electrode RE1 through the first via VIA1 penetrating (e.g., passing through) the planarization layer PLNL. The second anode electrode AE2 may be connected to the second reflective electrode RE2 through the second via VIA2 penetrating the planarization layer PLNL. The third anode electrode AE3 may be connected to the third reflective electrode RE3 through the third via VIA3 penetrating the planarization layer PLNL.

In one or more embodiments, the first to third anode electrodes AE1 to AE3 may include at least one transparent conductive material, such as an indium tin oxide (ITO), an indium zinc oxide (IZO), a zinc oxide (ZnOₓ, where 0<x≤1), an indium gallium zinc oxide (IGZO), and/or an indium tin zinc oxide (ITZO). However, the materials of the first to third anode electrodes AE1 to AE3 are not limited thereto. For example, the first to third anode electrodes AE1 to AE3 may include a titanium nitride.

In one or more embodiments, insulating layers for adjusting a height of one or more of the first to third anode electrodes AE1 to AE3 may be further provided. The insulating layers may be arranged between one or more of the first to third anode electrodes AE1 to AE3 and the corresponding reflective electrodes. In such embodiments, the planarization layer PLNL and/or the buffer pattern BFP may not be provided. For example, the first to third sub-pixels SP1 to SP3 may respectively correspond to red, green, and blue, and the distance between the first anode electrode AE1 and the cathode electrode CE may be shorter than the distance between the second anode electrode AE2 and the cathode electrode CE, and the distance between the second anode electrode AE2 and the cathode electrode CE may be shorter than the distance between the third anode electrode AE3 and the cathode electrode CE. The pixel-defining layer PDL is arranged on some of (portions of) the first to third anode electrodes AE1 to AE3 and the planarization layer PLNL. The pixel-defining layer PDL has an opening OP (e.g., openings OP) exposing a portion of each of the first to third anode electrodes AE1 to AE3. An area overlapping the pixel-defining layer PDL may be understood as a boundary area BDA between adjacent sub-pixels.

In one or more embodiments, the pixel-defining layer PDL may include a plurality of inorganic insulating layers. Each of the plurality of inorganic insulating layers may include at least one of a silicon oxide (SiOₓ) and/or a silicon nitride (SiNₓ). For example, the pixel-defining layer PDL may include a first inorganic insulating layer ISL1, a second inorganic insulating layer ISL2, and a third inorganic insulating layer ISL3 sequentially stacked. The first to third inorganic insulating layers ISL1 to ISL3 may include a silicon nitride, a silicon oxide, and/or a silicon oxynitride, but the present disclosure is not limited thereto. The first to third inorganic insulating layers ISL1 to ISL3 may have a step-shaped cross-section in an area adjacent to the opening OP (e.g., in each of the areas adjacent to the openings OP).

The pixel-defining layer PDL may include a separator SPR in the boundary area BDA between adjacent sub-pixels. For example, the separator SPR may be provided in each of the boundary areas between the sub-pixels SP in FIG. 3.

The separator SPR may cause a discontinuity to be formed within the light-emitting structure EMS in the boundary area BDA. For example, the light-emitting structure EMS may be disconnected and/or bent in the boundary area BDA by the separator SPR. Accordingly, the first to third light-emitting areas EMA1 to EMA3 of FIG. 6 respectively corresponding to the first to third sub-pixels SP1 to SP3 may be defined according to the separator SPR of the pixel-defining layer PDL.

The separator SPR may be provided in or on the pixel-defining layer PDL. The pixel-defining layer PDL may include one or more trenches TRCH1 and TRCH2 as the separator SPR in the boundary area BDA. In one or more embodiments, as shown in FIG. 6, one or more trenches TRCH1 and TRCH2 may penetrate the pixel-defining layer PDL and partially penetrate the planarization layer PLNL. In one or more embodiments, one or more trenches TRCH1 and TRCH2 may penetrate the pixel-defining layer PDL and the planarization layer PLNL, and may partially penetrate the via layer VIAL. In one or more embodiments, one or more trenches TRCH1 and TRCH2 at least partially penetrate the planarization layer PLNL and/or the via layer VIAL, and a portion of the pixel-defining layer PDL may be arranged in one or more trenches TRCH1 and TRCH2.

FIG. 6 illustrates that two trenches TRCH1 and TRCH2 are provided in the boundary region BDA. However, the present disclosure is not limited thereto. For example, the pixel-defining film PDL may include one trench in the boundary area BDA. In one or more embodiments, the pixel-defining layer PDL may include three or more trenches in the boundary area BDA.

Due to the first and second trenches TRCH1 and TRCH2, discontinuous portions such as the first void VD1 and the second void VD2 may be formed in the light-emitting structure EMS in the boundary area BDA. Some of the plurality of layers stacked in the light-emitting structure EMS may be disconnected and/or bent by the first and second voids VD1 and VD2. For example, at least one charge generation layer and at least one hole injection layer included in the light-emitting structure EMS may be disconnected in the first and second voids VD1 and VD2. As described above, due to the first and second trenches TRCH1 and TRCH2, portions of the light-emitting structure EMS included in the first to third sub-pixels SP1 to SP3 may be at least partially separated.

In FIG. 6, it is illustrated that the first and second voids VD1 and VD2 are formed in the light-emitting structure EMS in the boundary area BDA, but this is an example, and the present disclosure is not limited thereto. For example, a valley having a concave shape may be formed in the light-emitting structure EMS in the boundary area BDA. Depending on the shapes of the first and second trenches TRCH1 and TRCH2, the discontinuities formed in the light-emitting structure EMS may vary.

In one or more embodiments, the light-emitting structure EMS may be formed through processes such as vacuum deposition or inkjet printing. In such embodiments, the same materials as the light-emitting structure EMS may be arranged on the bottom surfaces of the first and second trenches TRCH1 and TRCH2 adjacent to the via layer VIAL.

The pixel-defining layer PDL may include an additional separator so that the light-emitting structure EMS further includes a discontinuous portion in the boundary area BDA. In one or more embodiments, the uppermost third inorganic insulating layer ISL3 among the first to third inorganic insulating layers ISL1 to ISL3 of the pixel-defining layer PDL may have a wider width than the second inorganic insulating layer ISL2 arranged directly below the third inorganic insulating layer. For example, the pixel-defining layer PDL may have a cross-section of a “T” or “I” shape in the boundary area BDA. Depending on the shape of the pixel-defining layer PDL, a plurality of layers included in the light-emitting structure EMS may be at least partially disconnected and/or bent in the boundary area BDA or in an area adjacent to the boundary area BDA.

The light-emitting structure EMS may be arranged on the anode electrodes AE exposed by the opening OP of the pixel-defining layer PDL. The light-emitting structure EMS may fill the opening OP of the pixel-defining layer PDL, and may be arranged entirely across the first to third sub-pixels SP1 to SP3. As described above, the light-emitting structure EMS may be at least partially disconnected and/or bent in the boundary area BDA by the separator SPR. Accordingly, if (e.g., when) the display panel DP operates, the current leaking from one of the first to third sub-pixels SP1 to SP3 to the neighboring sub-pixels through the layers included in the light-emitting structure EMS may decrease. Accordingly, the first to third light-emitting elements LD1 to LD3 may operate with relatively high reliability.

The cathode electrode CE may be arranged on the light-emitting structure EMS. The cathode electrode CE may be provided commonly for the first to third sub-pixels SP1 to SP3. The cathode electrode CE may function as a half mirror that partially transmits and partially reflects light emitted from the light-emitting structure EMS.

The first anode electrode AE1, the portion of the light-emitting structure EMS overlapping the first anode electrode AE1, and the portion of the cathode electrode CE overlapping the first anode electrode AE1 may constitute the first light-emitting element LD1. The second anode electrode AE2, the portion of the light-emitting structure EMS overlapping the second anode electrode AE2, and the portion of the cathode electrode CE overlapping the second anode electrode AE2 may constitute the second light-emitting element LD2. The third anode electrode AE3, the portion of the light-emitting structure EMS overlapping the third anode electrode AE3, and the portion of the cathode electrode CE overlapping the third anode electrode AE3 may constitute the third light-emitting element LD3.

The encapsulation layer TFE is arranged on the cathode electrode CE. The encapsulation layer TFE may prevent or reduce the likelihood of oxygen and/or moisture penetrating into the light-emitting element layer LDL.

The optical functional layer OFL is arranged on the encapsulation layer TFE. In one or more embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting the lower layers including the encapsulation layer TFE.

The optical functional layer OFL may include a color filter layer CFL and a lens array LA. The color filter layer CFL may include first to third color filters CF1 to CF3 respectively corresponding to the first to third sub-pixels SP1 to SP3. The first to third color filters CF1 to CF3 may pass (transmit) light in different wavelength ranges. For example, the first to third color filters CF1 to CF3 may pass red, green, and blue colored light, respectively.

In one or more embodiments, the first to third color filters CF1 to CF3 may partially overlap in the boundary area BDA. In one or more embodiments, the first to third color filters CF1 to CF3 may be spaced and/or apart (e.g., spaced apart or separated) from each other, and a black matrix may be provided between the first to third color filters CF1 to CF3.

The lens array LA is arranged on the color filter layer CFL. The lens array LA may include first to third lenses LS1 to LS3 respectively corresponding to the first to third sub-pixels SP1 to SP3. The first to third lenses LS1 to LS3 may improve light output efficiency by outputting the light emitted from the first to third light-emitting elements LD1 to LD3, respectively, along an intended path.

The overcoat layer OC may be arranged on the lens array LA. The overcoat layer OC is configured to protect its lower layers from foreign substances such as dust, moisture, and/or the like. The cover window CW may be arranged on the overcoat layer OC.

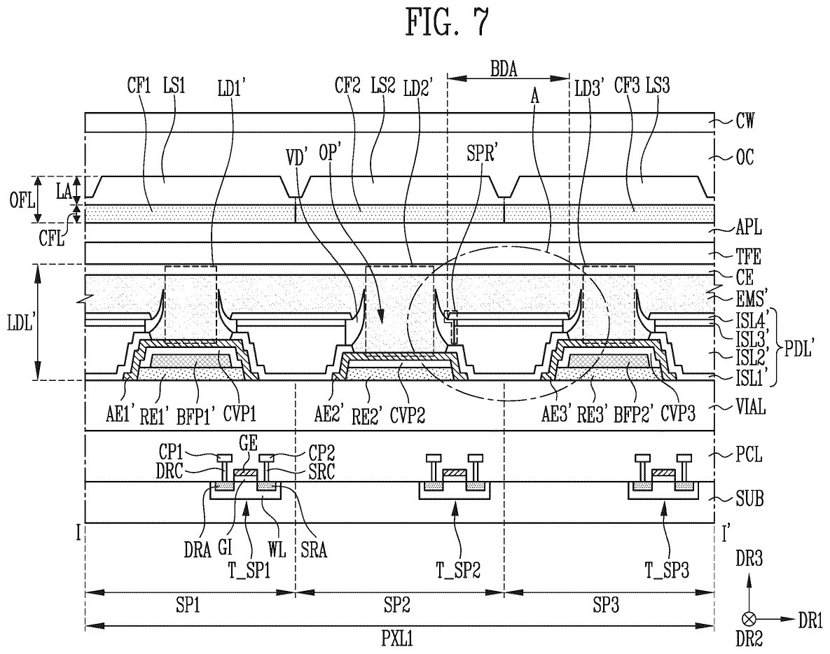

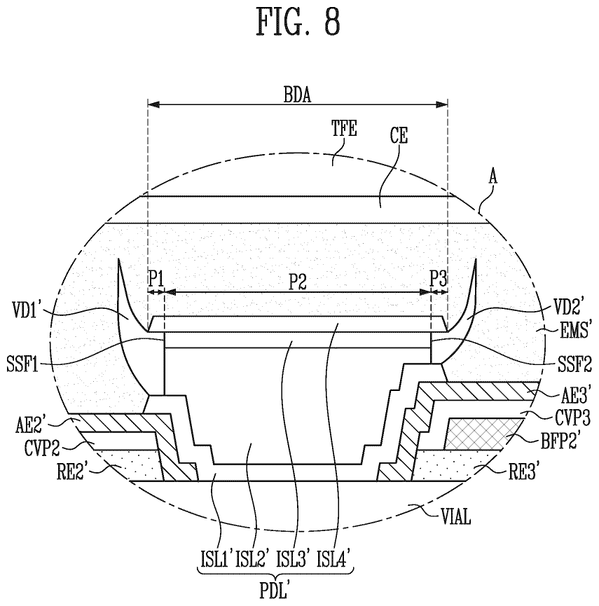

FIG. 7 is a schematic cross-sectional view taken along the line I-I′ of FIG. 5, according to one or more embodiments of the present disclosure. FIG. 7 illustrates a cross-section of the display area DA. FIG. 8 is a schematic enlarged view of area “A” of FIG. 7, according to one or more embodiments of the present disclosure.

Referring to FIG. 7, a pixel circuit layer PCL and a via layer VIAL are arranged on a substrate SUB. The substrate SUB, the pixel circuit layer PCL, and the via layer VIAL of FIG. 8 are configured similarly to the substrate SUB, the pixel circuit layer PCL, and the via layer VIAL of FIG. 6. Thus, redundant descriptions thereof may not be provided.

A light-emitting element layer LDL′ is arranged on the via layer VIAL. The light-emitting element layer LDL′ may include first to third reflective electrodes RE1′ to RE3′, first and second buffer patterns BFP1′ and BFP2′, first to third cover patterns CVP1 to CVP3, first to third anode electrodes AE1′ to AE3′, a pixel-defining layer PDL′, a light-emitting structure EMS′, and a cathode electrode CE.

The first to third reflective electrodes RE1′ to RE3′ are arranged in the first to third sub-pixels SP1 to SP3 on the via layer VIAL, respectively. Each of the first to third reflective electrodes RE1′ to RE3′ may contact a circuit element arranged in the pixel circuit layer PCL through a via penetrating the via layer VIAL.

The first to third reflective electrodes RE1′ to RE3′ are configured to reflect light emitted from the light-emitting structure EMS' toward the display surface (or the cover window CW). The first to third reflective electrodes RE1′ to RE3′ may include metallic materials suitable for reflecting light. The first to third reflective electrodes RE1′ to RE3′ may include at least one of aluminum (AI), silver (Ag), magnesium (Mg), platinum (Pt), palladium (Pd), gold (Au), nickel (Ni), neodymium (Nd), iridium (Ir), chromium (Cr), titanium (Ti), and/or an alloy of two or more materials selected therefrom, but the present disclosure is not limited thereto.

In one or more embodiments, a connection electrode may be further provided between each of the first to third reflective electrodes RE1′ to RE3′ and the via layer VIAL. The connection electrodes may improve electrical connection characteristics between each of the reflective electrodes and the corresponding circuit element of the pixel circuit layer PCL. The connection electrodes may each have a multi-layered structure. The multi-layered structure may include titanium (Ti), aluminum (AI), a titanium nitride (TiN), a tantalum nitride (TaN), and/or the like, but the present disclosure is not limited thereto. In one or more embodiments, a corresponding reflective electrode may be arranged between the multiple layers of the connection electrode.

A buffer pattern may be arranged on at least one of the first to third reflective electrodes RE1′ to RE3′. In one or more embodiments, the first and second buffer patterns BFP1′ and BFP2′ may be arranged on the first and third reflection electrodes RE1′ and RE3′, respectively. Heights of the first and third anode electrodes AE1′ and AE3′ in the third direction DR3 may be adjusted by the first and second buffer patterns BFP1′ and BFP2′. The first and second buffer patterns BFP1′ and BFP2′ may include an inorganic material such as a silicon oxide (SiOₓ) and/or a silicon nitride (SiNₓ), but the present disclosure is not limited thereto.

The first to third cover patterns CVP1 to CVP3 may be arranged on the first to third reflective electrodes RE1′ to RE3′, respectively. In the first sub-pixel SP1, the first cover pattern CVP1 may be arranged on the first reflective electrode RE1′ and the first buffer pattern BFP1′. In the second sub-pixel SP2, the second cover pattern CVP2 may be arranged on the second reflective electrode RE2′. In the third sub-pixel SP3, the third cover pattern CVP3 may be arranged on the third reflective electrode RE3′ and the second buffer pattern BFP2′. The first to third cover patterns CVP1 to CVP3 may be formed after the formation of the first and second buffer patterns BFP1′ and BFP2′ during the manufacturing process. The first to third cover patterns CVP1 to CVP3 may include the same material as the first and second buffer patterns BFP1′ and BFP2′. For example, the first to third cover patterns CVP1 to CVP3 may include inorganic materials such as a silicon oxide (SiOₓ) and/or a silicon nitride (SiNₓ), but the present disclosure is not limited thereto.

The first to third anode electrodes AE1′ to AE3′ are arranged on the first to third cover patterns CVP1 to CVP3, respectively. In one or more embodiments, the first anode electrode AE1′ may cover the first cover pattern CVP1, the first buffer pattern BFP1′, and the first reflection electrode RE1′. The second anode electrode AE2′ may cover the second cover pattern CVP2 and the second reflection electrode RE2′. The third anode electrode AE3′ may cover the third cover pattern CVP3, the second buffer pattern BFP2′, and the third reflective electrode RE3′.

The first to third anode electrodes AE1′ to AE3′ may be electrically connected to the first to third reflective electrodes RE1′ to RE3′, respectively. For example, each anode electrode may be connected to an end (or edge) of the corresponding reflective electrode. However, the present disclosure is not limited thereto. In order to improve the electrical connection characteristics between the anode electrode and the reflective electrode, the anode electrode may be connected to the reflective electrode in one or more suitable ways.

In one or more embodiments, the first to third anode electrodes AE1′ to AE3′ may include at least one transparent conductive material, such as an indium tin oxide (ITO), an indium zinc oxide (IZO), a zinc oxide (ZnOₓ), an indium gallium zinc oxide (IGZO), and/or an indium tin zinc oxide (ITZO). However, the materials of the first to third anode electrodes AE1′ to AE3′ are not limited thereto. For example, the first to third anode electrodes AE1′ to AE3′ may include a titanium nitride.

The first to third anode electrodes AE1′ to AE3′ may have shapes similar to the first to third light-emitting areas EMA1 to EMA3 of FIG. 5 when viewed in the third direction DR3.

The first to third anode electrodes AE1′ to AE3′ and the cathode electrode CE may partially reflect incident light. Light emitted from the light-emitting layer of the light-emitting structure EMS' may be amplified by reciprocating between the anode electrode and the cathode electrode CE, and may be outputted through the cathode electrode CE. For example, each anode electrode and the cathode electrode CE may provide a resonance structure in a corresponding sub-pixel. In such embodiments, the distance between each anode electrode and the cathode electrode CE may be understood as the resonance distance for the light emitted from the light-emitting layer of the corresponding light-emitting structure EMS.

The first to third sub-pixels SP1 to SP3 may correspond to red, green, and blue, respectively. In such embodiments, heights of the first and third anode electrodes AE1′ and AE3′ in the third direction DR3 may be higher than the second anode electrode AE2′ by the first and second buffer patterns BFP1′ and BFP2′. Accordingly, the first and third sub-pixels SP1 and SP3 may have a shorter resonance distance than the second sub-pixel SP2 due to the first and second buffer patterns BFP1′ and BFP2′. In this way, the resonance distance of each sub-pixel may be adjusted so that light in the wavelength range of the corresponding color is effectively and efficiently amplified.

In FIG. 7, the first and second buffer patterns BFP1′ and BFP2′ are shown to be respectively arranged below the first and third anode electrodes AE1′ and AE3′, but the present disclosure is not limited thereto. For example, one of the first and second buffer patterns BFP1′ and BFP2′ may not be provided. As another example, both the first and second buffer patterns BFP1′ and BFP2′ may not be provided. In such embodiments, the resonance distances between respective anode electrodes and the cathode electrode CE may be the same. As another example, a buffer pattern may be arranged below each of the first to third anode electrodes AE1′ to AE3′. In such embodiments, the buffer patterns arranged below respective anode electrodes may have different thicknesses, and accordingly, the resonance distances between respective anode electrodes and the cathode electrode CE may be different from each other. As described above, by providing the buffer pattern for adjusting the height of the anode electrode below at least one of the first to third anode electrodes AE1′ to AE3′, the resonance distance in each sub-pixel may be improved or optimized.

The pixel-defining layer PDL′ is arranged on portions of the first to third anode electrodes AE1′ to AE3′ and on the via layer VIAL. The pixel-defining layer PDL′ has an opening OP′ (e.g., openings OP′) exposing a portion of each of the first to third anode electrodes AE1′ to AE3′. An area overlapping the pixel-defining layer PDL′ may be understood as the boundary area BDA between adjacent sub-pixels.

The pixel-defining layer PDL′ may include a plurality of inorganic insulating layers sequentially stacked. Each of the plurality of inorganic insulating layers may include at least one of a silicon oxide (SiOₓ) and/or a silicon nitride (SiNₓ). However, the present disclosure is not limited thereto. For example, the pixel-defining layer PDL′ may include an organic insulating layer.

In one or more embodiments, the pixel-defining layer PDL′ may include first to fourth inorganic insulating layers ISL1′ to ISL4′. The first inorganic insulating layer ISL1′ may cover portions of the first to third anode electrodes AE1′ to AE3′ and the via layer VIAL. The second inorganic insulating layer ISL2′ is arranged on the first inorganic insulating layer ISL1′, the third inorganic insulating layer ISL3′ is arranged on the second inorganic insulating layer ISL2′, and the fourth inorganic insulating layer ISL4′ is arranged on the third inorganic insulating layer ISL3′. The first and third inorganic insulating layers ISL1′ and ISL3′ may include a silicon nitride (SiNₓ), and the second and fourth inorganic insulating layers ISL2′ and ISL4′ may include a silicon oxide (SiOₓ), but the present disclosure is not limited thereto. In one or more embodiments, the first inorganic insulating layer ISL1′ may not be provided.

The pixel-defining layer PDL′ may include a separator SPR′ in the boundary area BDA between adjacent sub-pixels. The separator SPR′ may cause a discontinuous part such as a void VD′ to be formed in the light-emitting structure EMS′. Due to the discontinuous portion, at least some of the plurality of layers included in the light-emitting structure EMS' may be disconnected and/or bent.

The fourth inorganic insulating layer ISL4′ may be wider than the second and third inorganic insulating layers ISL2′ and ISL3′. In such embodiments, side surfaces of the second to fourth inorganic insulating layers ISL2′ to ISL4′ adjacent to the opening OP′ may be provided as the separator SPR′.

Referring to FIG. 8 together with FIG. 7, the fourth inorganic insulating layer ISL4′ may include first to third portions P1 to P3. The second portion P2 may completely overlap the second and third inorganic insulating layers ISL2′ and ISL3′. The first portion P1 protrudes from the second portion P2 in a direction opposite to the first direction DR1. The third portion P3 protrudes from the second portion P2 in the first direction DR1. As such, a width of the fourth inorganic insulating layer ISL4′ may be wider than those of the second and third inorganic insulating layers ISL2′ and ISL3′. For example, during the manufacturing process, the second and third inorganic insulating layers ISL2′ and ISL3′ may be undercut so as not to include portions overlapping the first and third portions P1 and P3. For example, each of the first and third portions P1 and P3 of the fourth inorganic insulating layer ISL4′ may have the shape of an eaves on each of the second and third inorganic insulating layers ISL2′ and ISL3′.

In the boundary area BDA, the second and third inorganic insulating layers ISL2′ and ISL3′ may have the same width. However, the present disclosure is not limited thereto, and the second and third inorganic insulating layers ISL2′ and ISL3′ may have different widths. For example, the second inorganic insulating layer ISL2′ may have a wider width than the third inorganic insulating layer ISL3′. As another example, the third inorganic insulating layer ISL3′ may have a wider width than the second inorganic insulating layer ISL2′.

In the second sub-pixel SP2, the first portion P1 of the fourth inorganic insulating layer ISL4′ and the first side surface SSF1 of the second and third inorganic insulating layers ISL2′ and ISL3′ may be provided as one separator SPR′. Accordingly, the first void VD1′ adjacent to the first portion P1 of the fourth inorganic insulating layer ISL4′ may be formed in the light-emitting structure EMS′. In the third sub-pixel SP3, the third portion P3 of the fourth inorganic insulating layer ISL4′ and the second side surface SSF2 of the second and third inorganic insulating layers ISL2′ and ISL3′ may be provided as another separator SPR′. Accordingly, the second void VD2′ adjacent to the third portion P3 of the fourth inorganic insulating layer ISL4′ may be formed in the light-emitting structure EMS′.

Some of the plurality of layers stacked in the light-emitting structure EMS may be disconnected and/or bent by the first and second voids VD1′ and VD2′. For example, at least one charge generation layer and at least one hole injection layer included in the light-emitting structure EMS may be disconnected by the first and second voids VD1′ and VD2′. As described above, due to the separator SPR′, the portions of the light-emitting structure EMS' included in the first to third sub-pixels SP1 to SP3 may be at least partially separated from each other.

The pixel-defining layer PDL′ may include an additional separator so that the light-emitting structure EMS' further includes a discontinuous portion in the boundary area BDA. In one or more embodiments, the pixel-defining layer PDL′ may include one or more trenches as a separator in the boundary area BDA. The trenches may penetrate (e.g., pass through) one or more of the first to fourth inorganic insulating layers ISL1′ to ISL4′. Due to the trenches, some of the plurality of layers stacked in the light-emitting structure EMS′, for example, at least one charge generation layer and at least one hole injection layer, may be disconnected and/or bent. In one or more embodiments, the light-emitting structure EML may have a structure in which three light-emitting portions each including a light-emitting layer are stacked, and two charge generation layers may be arranged between the three light-emitting portions. In one or more embodiments, the pixel-defining layer PDL′ may include one or more trenches in the boundary area BDA.

Referring again to FIG. 7, the light-emitting structure EMS' may be arranged on the anode electrodes AE exposed by the opening OP′ of the pixel-defining layer PDL′. The light-emitting structure EMS' may fill the opening OP′ of the pixel-defining layer PDL′, and may be arranged entirely across the first to third sub-pixels SP1 to SP3. As described above, the light-emitting structure EMS' may be disconnected and/or bent in the boundary area BDA or an area adjacent to the boundary area BDA by the separator SPR′. Accordingly, during the operation of the display panel DP, the current flowing between each of the first to third sub-pixels SP1 to SP3 through the layers included in the light-emitting structure EMS' may decrease. Accordingly, the first to third light-emitting elements LD1′ to LD3′ may operate with relatively high reliability.

In one or more embodiments, the light-emitting structure EMS' may include two light-emitting portions sequentially stacked, and each of the light-emitting portions may include a light-emitting layer configured to generate and/or emit light according to an applied current. In one or more embodiments, the light-emitting structure EMS' may include three light-emitting portions sequentially stacked, and each of the light-emitting portions may include a light-emitting layer configured to generate and/or emit light according to an applied current. In these embodiments, a charge generation layer may be arranged between the light-emitting portions.

In one or more embodiments, the light-emitting structure EMS' may be formed through processes such as vacuum deposition or inkjet printing.

The cathode electrode CE may be arranged on the light-emitting structure EMS′. The cathode electrode CE may be provided commonly across the first to third sub-pixels SP1 to SP3.

The first anode electrode AE1′, the portion of the light-emitting structure EMS' overlapping the first anode electrode AE1′, and the portion of the cathode electrode CE overlapping the first anode electrode AE1′ may constitute the first light-emitting element LD1′. The second anode electrode AE2′, the portion of the light-emitting structure EMS' overlapping the second anode electrode AE2′, and the portion of the cathode electrode CE overlapping the second anode electrode AE2′ may constitute the second light-emitting element LD2′. The third anode electrode AE3′, the portion of the light-emitting structure EMS' overlapping the third anode electrode AE3′, and the portion of the cathode electrode CE overlapping the third anode electrode AE3′ may constitute the third light-emitting element LD3′.

The encapsulation layer TFE may be arranged on the cathode electrode CE. The encapsulation layer TFE may prevent or reduce the likelihood of oxygen and/or moisture penetrating into the light-emitting element layer LDL′.

An adhesive layer APL, an optical functional layer OFL, an overcoat layer OC, and a cover window CW may be arranged on the encapsulation layer TFE. The adhesive layer APL, the optical functional layer OFL, the overcoat layer OC, and the cover window CW are configured similarly to the adhesive layer APL, the optical functional layer OFL, the overcoat layer OC, and the cover window CW of FIG. 6, respectively. Thus, duplicate descriptions of these may not be provided.

FIG. 9 is a schematic cross-sectional view of a non-display area of a display device, according to one or more embodiments of the present disclosure. Referring to FIG. 9, the display device 100 may further include a first insulating layer INS1, a second insulating layer INS2, a connection line CL, a dam portion DAM, and an organic insulating layer OL.

The first insulating layer INS1 and the second insulating layer INS2 are arranged on the substrate SUB. The second insulating layer INS2 may be arranged on the first insulating layer INS1. The first insulating layer INS1 and the second insulating layer INS2 may be some of the insulating layers included in the pixel circuit layer PCL. For example, the first insulating layer INS1 and the second insulating layer INS2 may be layers formed in substantially the same process as some of the insulating layers included in the pixel circuit layer PCL. For example, the first insulating layer INS1 may be a layer formed in substantially the same process as the gate insulating layer GI shown in FIG. 6 and FIG. 7.

The connection line CL may be arranged on the first insulating layer INS1. The connection line CL may be electrically connected to the pad PD. In one or more embodiments, the connection line CL may be at least one of lines that is to transmit signals to the gate line, the light-emitting control line, and/or the data line.

The connection line CL may include a conductive material. In one or more embodiments, the connection line CL may be formed in substantially the same process as the gate electrode GE. However, the present disclosure is not limited thereto, and the connection line CL may be formed concurrently (e.g., simultaneously) with at least one of one or more suitable conductive layers forming the transistors T_SP1, T_SP2, and/or T_SP3. The connection line CL may have a single layer structure or a multilayer structure including a plurality of conductive layers.

The dam part DAM may be arranged in the non-display area NDA between the display area DA and the pad portion PDA. When one component is formed by an inkjet method that ejects ink or a solution, the dam portion DAM may prevent or reduce overflow in the edge direction (for example, the right direction of FIG. 9) of the substrate SUB. For example, the dam portion DAM may have a shape around (e.g., surrounding) the display area DA in a plan view.

The organic insulating layer OL may be arranged on the pad PD. The organic insulating layer OL may define an opening exposing a portion (for example, a central portion) of the upper surface of the pad PD. The conductive adhesive member 200 and the circuit board 300 may be attached onto the portion of the upper surface of the pad PD exposed by the opening of the organic insulating layer OL. The circuit board 300 may be electrically connected to the pad PD through the conductive adhesive member 200.

At least a portion of the upper surface of the pad PD may not be in contact with an inorganic insulating film. The upper surface of the pad PD may be defined as a surface opposite to the surface facing (e.g., opposite to) the substrate SUB. The display device 100 according to the present disclosure is characterized in that no inorganic residual film is formed on the pad PD. In the display device DD according to the present disclosure, an inorganic residual film may not be formed on the pad PD, and the upper surface of the pad PD may not be in contact with an inorganic residual film.

The inorganic residual film may be a layer formed if (e.g., when) an inorganic insulating film is formed on the substrate SUB after the pad PD is formed. For example, after forming an inorganic insulating film on the substrate SUB to cover one component on the substrate SUB, an etching process may be performed to expose at least a portion of the pad PD. In such embodiments, if (e.g., when) the inorganic insulating film in contact with the pad PD is not completely removed in the etching process, an inorganic residual film may be formed on the pad PD. When the inorganic residual film is formed, the resistance of the pad PD increases, thereby increasing the driving voltage of the display device 100 and decreasing the reliability of the display device 100.

The inorganic residual film is a layer formed if (e.g., when) an inorganic insulating film is formed on the substrate SUB after the pad PD is formed, and may include, for example, a silicon nitride (SiNₓ), a silicon oxide (SiOₓ), a silicon carbon nitride (SiCN), a silicon oxynitride (SiOₓN_{y}), and/or aluminum oxide (AlOₓ). The inorganic insulating film may include, for example, an encapsulation layer TFE. For example, the encapsulation layer TFE may not be in contact with the pad PD, and may not overlap the pad PD in a plan view. In the above, it is described that the inorganic insulating film is the encapsulation layer TFE as an example, but the present disclosure is not limited thereto.

FIG. 10 is a cross-sectional view of a portion of a light-emitting structure included in one of first to third light-emitting elements of FIG. 6 or FIG. 7 according to one or more embodiments of the present disclosure.

Referring to FIG. 10, the light-emitting structure may have a tandem structure in which first and second light-emitting portions EU1 and EU2 are stacked. The light-emitting structure may be configured to be substantially the same in each of the first to third light-emitting elements LD1 to LD3 of FIG. 6 or FIG. 7.

Each of the first and second light-emitting portions EU1 and EU2 may include at least one light-emitting layer that is to generate and/or emit light according to a current applied thereto. The first light-emitting portion EU1 may include a first light-emitting layer EML1, a first electron transport portion ETU1, and a first hole transport portion HTU1. The first light-emitting layer EML1 may be arranged between the first electron transport portion ETU1 and the first hole transport portion HTU1. The second light-emitting portion EU2 may include a second light-emitting layer EML2, a second electron transport portion ETU2, and a second hole transport portion HTU2. The second light-emitting layer EML2 may be arranged between the second electron transport portion ETU2 and the second hole transport portion HTU2.

Each of the first and second hole transport portions HTU1 and HTU2 may include at least one of a hole injection layer and/or a hole transport layer, and may further include a hole buffer layer, an electron blocking layer, and/or the like as desired and/or needed. The first and second hole transport portions HTU1 and HTU2 may have the same configuration or different configurations.

Each of the first and second electron transport portions ETU1 and ETU2 may include at least one of an electron injection layer and/or an electron transport layer, and may further include an electron buffer layer and/or a hole blocking layer as desired and/or needed. The first and second electron transport portions ETU1 and ETU2 may have the same configuration or different configurations.

A connection layer, which may be provided in the form of a charge generation layer CGL, may be arranged between the first light-emitting portion EU1 and the second light-emitting portion EU2 to connect them to each other. In one or more embodiments, the charge generation layer CGL may have a stacked structure of a p dopant layer and an n dopant layer. For example, the p dopant layer may include a p-type (kind) dopant such as hexaazatriphenylenehexacarbonitrile (HAT-CN), tetracyanoquinodimethane (TCNQ), and/or 2-(7-dicyanomethylene-1,3,4,5,6,8,9,10-octafluoro-7H-pyrene-2-ylidene)-malononitrile (NDP-9), and the n dopant layer may include an alkali metal, an alkaline earth metal, a lanthanide-based metal, and/or a (e.g., any suitable) combination thereof. However, the present disclosure is not limited thereto.

In one or more embodiments, the first light-emitting layer EML1 and the second light-emitting layer EML2 may generate and/or emit light of different colors. The light emitted from each of the first light-emitting layer EML1 and the second light-emitting layer EML2 may be mixed to be recognized as white light. For example, the first light-emitting layer EML1 may generate blue-colored light, and the second light-emitting layer EML2 may generate yellow-colored light. In one or more embodiments, the second light-emitting layer EML2 may include a structure in which a first sub-light-emitting layer configured to generate red-colored light and a second sub-light-emitting layer configured to generate green-colored light are stacked. The red-colored light and the green-colored light may be mixed to provide yellow-colored light. In such embodiments, an intermediate layer configured to perform a function of transporting holes and/or preventing or reducing the transport of electrons may be further arranged between the first and second sub-light emitting layers.

In one or more embodiments, the first light-emitting layer EML1 and the second light-emitting layer EML2 may generate and/or emit light of the same color.

The light-emitting structure may be formed through a vacuum deposition method, an inkjet printing method, and/or the like, but the present disclosure is not limited thereto.

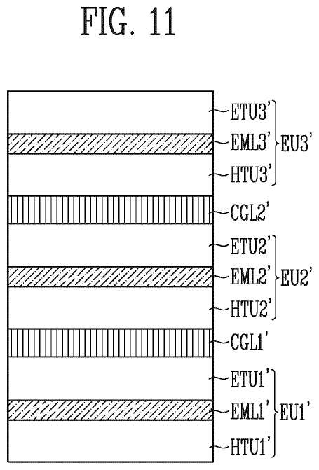

FIG. 11 is a cross-sectional view of a portion of a light-emitting structure included in one of first to third light-emitting elements of FIG. 6 or FIG. 7, according to one or more embodiments of the present disclosure.

Referring to FIG. 11, the light-emitting structure may have a tandem structure in which first to third light-emitting portions EU1′ to EU3′ are stacked. The light-emitting structure may be configured to be substantially the same in each of the first to third light-emitting elements LD1 to LD3 of FIG. 6 or FIG. 7.

Each of the first to third light-emitting portions EU1′ to EU3′ may include a light-emitting layer that is to generate and/or emit light according to a current applied thereto. The first light-emitting portion EU1′ may include a first light-emitting layer EML1′, a first electron transport portion ETU1′, and a first hole transport portion HTU1′. The first light-emitting layer EML1′ may be arranged between the first electron transport portion ETU1′ and the first hole transport portion HTU1′. The second light-emitting portion EU2′ may include a second light-emitting layer EML2′, a second electron transport portion ETU2′, and a second hole transport portion HTU2′. The second light-emitting layer EML2′ may be arranged between the second electron transport portion ETU2′ and the second hole transport portion HTU2′. The third light-emitting portion EU3′ may include a third light-emitting layer EML3′, a third electron transport portion ETU3′, and a third hole transport portion HTU3′. The third light-emitting layer EML3′ may be arranged between the third electron transport portion ETU3′ and the third hole transport portion HTU3′.

Each of the first to third hole transport portions HTU1′ to HTU3′ may include at least one of a hole injection layer and/or a hole transport layer, and may further include a hole buffer layer, an electron blocking layer, and/or the like as desired and/or needed. The first to third hole transport portions HTU1′ to HTU3′ may have the same configuration or different configurations.

Each of the first to third electron transport portions ETU1′ to ETU3′ may include at least one of an electron injection layer and/or an electron transport layer, and may further include an electron buffer layer and/or a hole blocking layer as desired and/or needed. The first to third electron transport portions ETU1′ to ETU3′ may have the same configuration or different configurations.

A first charge generation layer CGL1′ is arranged between the first light-emitting portion EU1′ and the second light-emitting portion EU2′. A second charge generation layer CGL2′ is arranged between the second light-emitting portion EU2′ and the third light-emitting portion EU3′.

In one or more embodiments, the first to third light-emitting layers EML1′ to EML3′ may generate and/or emit light of different colors. Light emitted from each of the first to third light-emitting layers EML1′ to EML3′ may be mixed to be viewed as white light. For example, the first light-emitting layer EML1′ may generate and/or emit light of a blue color, the second light-emitting layer EML2′ may generate and/or emit light of a green color, and the third light-emitting layer EML3′ may generate and/or emit light of a red color.

In one or more embodiments, two or more of the first to third light-emitting layers EML1′ to EML3′ may generate light of the same color.

Unlike shown in FIG. 10 and FIG. 11, the light-emitting structure EMS of FIG. 6 or FIG. 7 may include one light-emitting portion in each of the first to third light-emitting elements LD1 to LD3. In such embodiments, the light-emitting portions respectively included in the first to third light-emitting elements LD1 to LD3 may be configured to emit light of different colors. For example, the light-emitting portion of the first light-emitting element LD1 may be to emit red-colored light, the light-emitting portion of the second light-emitting element LD2 may be to emit green-colored light, and the light-emitting portion of the third light-emitting element LD3 may be to emit bluecolored light. In such embodiments, the light-emitting portions of the first to third sub-pixels SP1 to SP3 are separated from each other, and each of them may be arranged within the opening OP (see, e.g., the opening OP in FIG. 6 and the opening OP′ in FIG. 7) of the pixel-defining layer PDL (see, e.g., the pixel-defining layer PDL in FIG. 6 and the pixel-defining layer PDL′ in FIG. 7).

In such embodiments, at least some of the color filters CF1 to CF3 may not be provided.

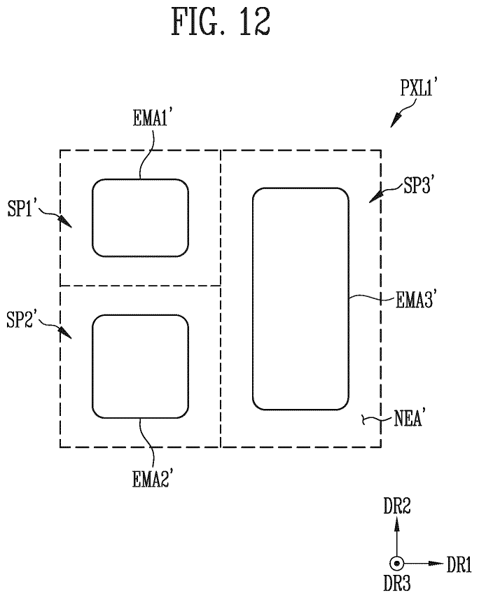

FIG. 12 is a schematic top plan view of a pixel according to one or more embodiments of the present disclosure.

Referring to FIG. 12, a first pixel PXL1′ may include first to third sub-pixels SP1′ to SP3′.

The first sub-pixel SP1′ may include a first light-emitting area EMA1′ and a non-light emitting area NEA′ around the first light-emitting area EMA1′. The second sub-pixel SP2′ may include a second light-emitting area EMA2′ and the non-light emitting area NEA′ around the second light-emitting area EMA2′. The third sub-pixel SP3′ may include a third light-emitting area EMA3′ and the non-light emitting area NEA′ around the third light-emitting area EMA3′.

The first sub-pixel SP1′ and the second sub-pixel SP2′ may be arranged in the second direction DR2. The third sub-pixel SP3′ may be arranged in the first direction DR1 with respect to each of the first and second sub-pixels SP1′ and SP2′.

The second sub-pixel SP2′ may have a larger area than the first sub-pixel SP1′, and the third sub-pixel SP3′ may have a larger area than the second sub-pixel SP2′. Accordingly, the second light-emitting area EMA2′ may have a larger area than the first light-emitting area EMA1′, and the third light-emitting area EMA3′ may have a larger area than the second light-emitting area EMA2′. However, the present disclosure is not limited thereto. For example, the first and second sub-pixels SP1′ and SP2′ may have substantially the same area, and the third sub-pixel SP3′ may have a larger area than each of the first and second sub-pixels SP1′ and SP2′. As such, the areas of the first to third sub-pixels SP1′ to SP3′ may be variously modified according to one or more embodiments.

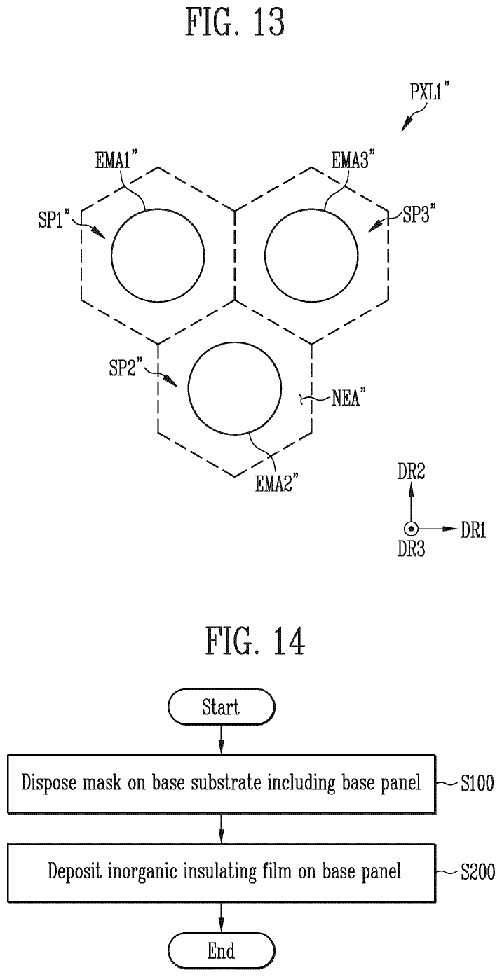

FIG. 13 is a schematic top plan view of a pixel, according to one or more embodiments of the present disclosure.

Referring to FIG. 13, the first sub-pixel SP1″ may include a first light-emitting area EMA1″ and a non-light emitting area NEA″ around the first light-emitting area EMA1″. The second sub-pixel SP2″ may include a second light-emitting area EMA2″ and the non-light emitting area NEA″ around the second light-emitting area EMA2″. The third sub-pixel SP3″ may include a third light-emitting area EMA3″ and the non-light emitting area NEA″ around the third light-emitting area EMA3″.

The first to third sub-pixels SP1″ to SP3″ may have polygonal shapes when viewed in the third direction DR3. For example, the first to third sub-pixels SP1″ to SP3″ may have hexagonal shapes, as shown in FIG. 13.

The first to third light-emitting areas EMA1″ to EMA3″ may have circular shapes when viewed in the third direction DR3. However, the present disclosure is not limited thereto. For example, each of the first to third light-emitting areas EMA1″ to EMA3″ may have a polygonal shape.

The first and third sub-pixels SP1″ and SP3″ may be arranged in the first direction DR1. The second sub-pixel SP2″ may be arranged in a direction (or a diagonal direction) inclined by an acute angle from the second direction DR2 with respect to the first sub-pixel SP1″.

The dispositions of the sub-pixels illustrated in FIGS. 5, 12, and 13 are merely examples, and the present disclosure is not limited thereto

Each pixel may include two or more sub-pixels, the sub-pixels may be variously arranged, each of the sub-pixels may have one or more suitable shapes, and each of its light-emitting areas may also have one or more suitable shapes.

Hereinafter, a method of manufacturing the display device 100 and a mask MSK used in manufacturing the display device 100 will be described with reference to FIG. 14 to FIG. 18.

FIG. 14 is a flowchart of a method of manufacturing a display device according to one or more embodiments of the present disclosure. Referring to FIG. 14, the method of manufacturing the display device 100 may include disposing and/or placing a mask on a base substrate including a base panel (S100) and depositing an inorganic insulating film on the base panel (S200).

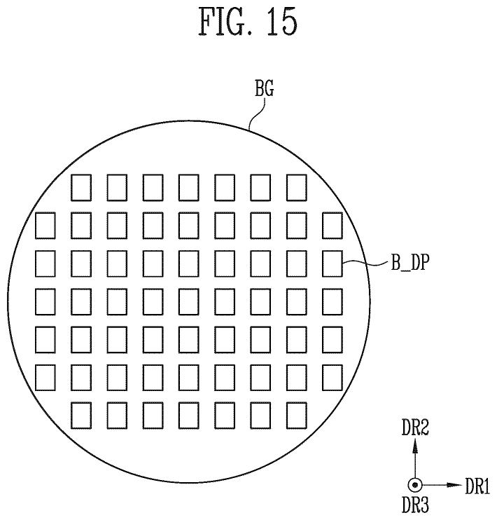

FIG. 15 is a schematic top plan view of a base substrate according to one or more embodiments of the present disclosure. Referring to FIG. 15, a base substrate BG may include a base panel B_DP. In one or more embodiments, a plurality of base panels B_DP may be provided. For example, the base substrate BG may include a plurality of base panels B_DP spaced and/or apart (e.g., spaced apart or separated) from each other.

The base substrate BG may be a wafer substrate for manufacturing an OLED on silicon (OLEDOS) display device. For example, the base substrate BG may include a silicon wafer substrate formed using a semiconductor process.

In the display panel DP shown in FIG. 9, the base panel B_DP may refer to the display panel DP before the conductive adhesive member 200 and the circuit board 300 are formed. For example, the base panel B_DP may refer to the display panel DP before the conductive adhesive member 200 and the circuit board 300 are formed after the pads PD are formed. For example, the base panel B_DP may include the display area DA and the non-display area NDA just like the display panel DP, and the pads PD may be formed in the non-display area NDA. The base panel B_DP may include the pad portion PDA.

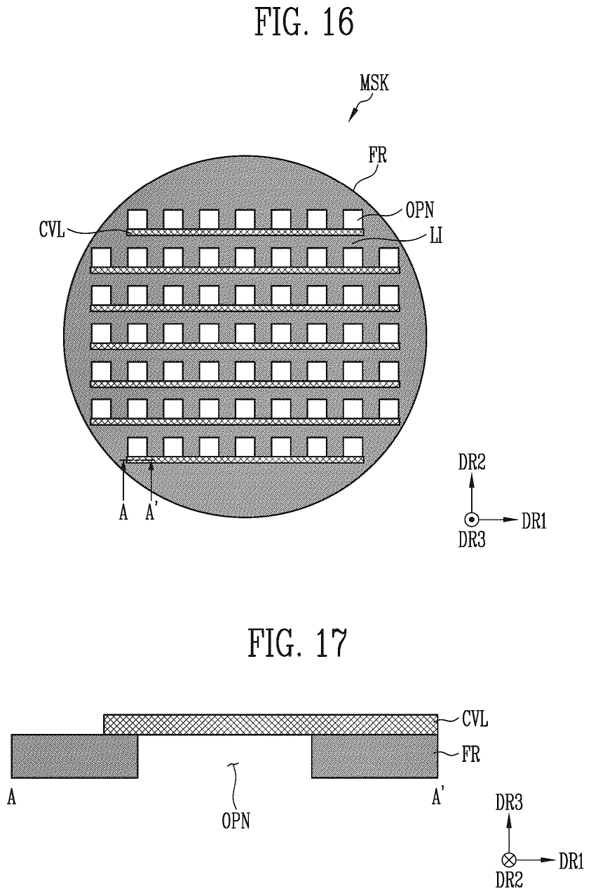

FIG. 16 is a schematic top plan view of a mask according to one or more embodiments of the present disclosure. FIG. 17 is a schematic cross-sectional view taken along the line A-A′ of FIG. 16, according to one or more embodiments of the present disclosure.

Referring to FIG. 16 and FIG. 17, the mask MSK may include a frame FR including an opening OPN and ribs LI defining the opening OPN, and a coating layer CVL. In one or more embodiments, a plurality of openings OPN may be provided. For example, a plurality of openings OPN may be formed in the frame FR of the mask MSK.

The ribs LI may be arranged adjacent to the opening OPN to define the opening OPN. For example, the ribs LI may be arranged between the openings OPN to define the openings OPN of the frame FR.

In one or more embodiments, the ribs LI may be integrally formed with the frame FR. In one or more embodiments, the ribs LI may be coupled to the frame FR to be assemble-able (or detachable).

The frame FR and each of the ribs LI may include at least one of a metal, polymer, carbon fiber reinforced plastic (CFRP), and/or ceramic. The metal may include, for example, at least one of stainless steel, Invar (64FeNi), molybdenum (Mo), tungsten (W), nickel (Ni), aluminum (AI), titanium (Ti), chromium (Cr), copper (Cu), cobalt (Co), gold (Au), silver (Ag), platinum (Pt), and/or palladium (Pd). The polymer may include, for example, at least one of polytetrafluoroethylene (PTFE), polybenzimidazole (PBI), polyimide (PI), polyether ether ketone (PEEK), polysulfone (PSU), polyphenylene sulfide (PPS), polyetherimide (PEI, Ultem), polyvinylidene fluoride (PVDF), polyfluoroalkylene (PFA), polysulfide (PES), polyphenylsulfone (PPSU), polypara-phenylene terephthalamide (PPTA), and/or fluorinated ethylene propylene (FEP). The frame FR and the ribs LI according to one or more embodiments of the present disclosure may include at least one of a metal, polymer, carbon fiber reinforced plastic, and/or ceramic, so that the mask MSK may have heat resistance and so that the possibility of the mask MSK being corroded by corrosive gas may be reduced.

The coating layer CVL may be arranged on the frame FR. The coating layer CVL may be arranged on the ribs LI, and at least a portion of the coating layer CVL may overlap at least a portion of the ribs LI in a plan view. At least a portion of the coating layer CVL may contact at least a portion of the ribs LI. The coating layer CVL may be arranged to cross the openings OPN. The coating layer CVL may cover a portion of each of the openings OPN. The coating layer CVL may cover a portion of each of the openings OPN and expose the remaining portion that is not covered. For example, the coating layer CVL may overlap a portion (or a first portion) of each of the openings OPN in a plan view, and may not overlap the remaining portion (or second portion) that is not covered by the coating layer CVL except for the first portion in a plan view.

The coating layer CVL may include at least one of a metal, polymer, carbon fiber reinforced plastic (CFRP), and/or ceramic. The metal may include, for example, at least one of stainless steel, Invar, molybdenum (Mo), tungsten (W), nickel (Ni), aluminum (AI), titanium (Ti), chromium (Cr), copper (Cu), cobalt (Co), gold (Au), silver (Ag), platinum (Pt), and/or palladium (Pd). The polymer may include, for example, at least one of polytetrafluoroethylene (PTFE), polybenzimidazole (PBI), polyimide (PI), polyether ether ketone (PEEK), polysulfone (PSU), polyphenylene sulfide (PPS), polyetherimide (PEI, Ultem), polyvinylidene fluoride (PVDF), polyfluoroalkylene (PFA), polysulfide (PES), polyphenylsulfone (PPSU), polypara-phenylene terephthalamide (PPTA), and/or fluorinated ethylene propylene (FEP). The coating layer CVL according to one or more embodiments of the present disclosure may include at least one of a metal, polymer, carbon fiber reinforced plastic, and/or ceramic, so that the mask MSK may have heat resistance and so that the possibility of the mask MSK being corroded by corrosive gas may be reduced.

The coating layer CVL may be formed through a coating process. The coating layer CVL is formed through a coating process so that the mask MSK may be more easily cleaned by a cleaning gas (for example, NH₃ or CH₄). When the mask MSK does not include the coating layer CVL, a deposition material formed on the mask MSK after the deposition process may not be cleaned by the cleaning gas, and a larger amount thereof may remain, compared to the case in which the mask MSK includes the coating layer CVL.

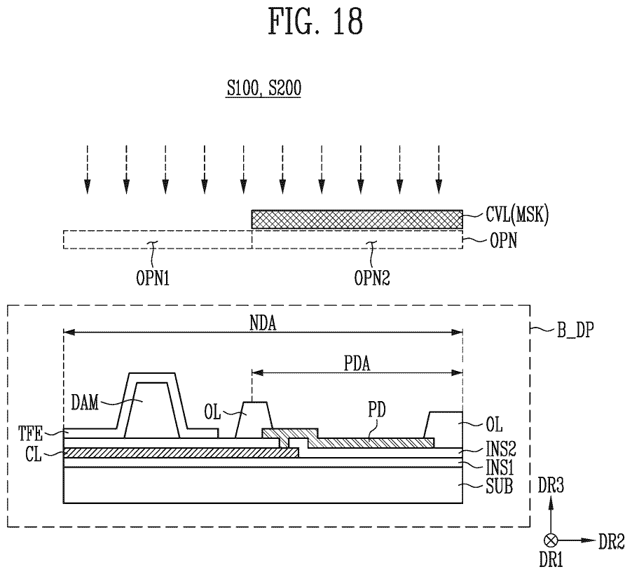

FIG. 18 is a cross-sectional view of process steps of a method of manufacturing a display device according to one or more embodiments of the present disclosure. In FIG. 18, for clear and concise description, the inorganic insulating film deposited in the depositing of the inorganic insulating film on the base panel of FIG. 14 (S200) is shown as the encapsulation layer TFE. However, the present disclosure is not limited thereto, and the inorganic insulating film deposited in the depositing of the inorganic insulating film (S200) may correspond to any layer including an inorganic insulating material among all the layers formed on the substrate SUB after the pad PD is formed.

Referring to FIG. 18, in the disposing and/or placing of the mask on the base substrate including the base panel (S100), the mask MSK may be arranged on the base panel B_DP. In one or more embodiments, the mask MSK may be arranged so that a surface of the coating layer CVL in contact with the rib LI (for example, a lower surface of the coating layer CVL) is directed toward the base panel B_DP, and in other embodiments, the mask MSK may be arranged so that a surface of the coating layer CVL that is not in contact with the rib LI (for example, an upper surface of the coating layer CVL) is directed toward the base panel B_DP.

The disposing of the mask on the base substrate including the base panel (S100) may include disposing the mask MSK on the base substrate BG so that each of the openings OPN of the mask MSK shown in FIG. 16 corresponds to each of the base panels B_DP shown in FIG. 15. Each of the openings OPN of the mask MSK may overlap each of the base panels B_DP in a plan view.

The disposing of the mask on the base substrate including the base panel (S100) may include disposing the mask MSK on the base substrate BG so that the coating layer CVL of the mask MSK corresponds to the pad portion PDA of each of the base panels B_DP. The coating layer CVL of the mask MSK may overlap the pad portion PDA of the base panels B_DP in a plan view. The coating layer CVL of the mask MSK may cover the pad portion PDA so that an inorganic insulating film is not deposited on the pad portion PDA of the base panels B_DP.

The depositing of the inorganic insulating film on the base panel (S200) may include depositing the inorganic insulating film after the pad PD is formed. The depositing of the inorganic insulating film on the base panel (S200) may include depositing an inorganic insulating film using at least one of chemical vapor deposition, sputtering, atomic layer deposition, and/or electron beam deposition.

The depositing of the inorganic insulating layer on the base panel (S200) may include depositing an inorganic insulating film through the opening OPN. The opening OPN may include a first portion OPN1 that does not overlap the coating layer CVL in a plan view and a second portion OPN2 that overlaps the coating layer CVL in a plan view. The first portion OPN1 may expose areas excluding the pad portion PDA of the base display panel B_DP, and an inorganic insulating film may be deposited through the first portion OPN1. An inorganic insulating film may be deposited in an area overlapping the first portion OPN1 in a plan view, and an inorganic insulating film may not be deposited in an area overlapping the second portion OPN2 in a plan view.

For example, if (e.g., when) forming the inorganic insulating film after forming a base panel B_DP so that the base panel B_DP includes the pixel circuit layer PCL and the light-emitting element layer LDL, the depositing of the inorganic insulating film on the base panel (S200) may include forming the encapsulation layer TFE on the light-emitting element layer LDL so that it does not overlap the pad portion PDA in a plan view. The mask MSK may be arranged on the light-emitting element layer LDL, and the encapsulation layer TFE may not be formed in the pad portion PDA, which is an area overlapping the second portion OPN2 in a plan view. The encapsulation layer TFE may not overlap the pad portion PDA in a plan view. The encapsulation layer TFE may not be in contact with the pad PD.

The depositing of the inorganic insulating film on the base panel (S200) may include depositing the inorganic insulating film not to be in contact with the upper surface of the pad PD. The upper surface of the pad PD may not be in physical contact with the inorganic insulating film, and thus the risk of an increase in the driving voltage of the display device 100 may be reduced. Because the risk of an increase in the driving voltage of the display device 100 is reduced, the defect rate of the display device 100 may be reduced, and the reliability of the display device 100 may be increased.

In one or more embodiments, because the inorganic insulating film is not formed in the area overlapping the second portion OPN2, the inorganic insulating film may not be further etched compared to the case in which the inorganic insulating film is also formed in the second portion OPN2. Accordingly, the manufacturing process of the display device 100 may be simplified, and the manufacturing cost may be reduced.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic apparatus, manufacturing methods or components for manufacturing (e.g., a mask), or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A method comprising:
placing a mask on a base substrate, the base substrate comprising a base panel that comprises:
a display area, and
a pad portion on a side of the display area and in which a pad is located; and
depositing an inorganic insulating film on the base panel,
wherein the mask comprises:
a frame comprising ribs defining an opening; and
a coating layer on the frame, and
wherein the placing of the mask comprises placing the mask so that the opening of the mask overlaps the base panel in a plan view and the coating layer overlaps the pad portion in a plan view, and
wherein the method is a method of manufacturing a display device.

2. The method of claim 1, wherein the coating layer covers a portion of the opening.

3. The method of claim 1, wherein
the opening has a first portion that does not overlap the coating layer in a plan view, and a second portion that overlaps the coating layer in a plan view, and
the depositing of the inorganic insulating film comprises depositing the inorganic insulating film through the first portion.

4. The method of claim 3, wherein the depositing of the inorganic insulating film does not deposit the inorganic insulating film in an area overlapping the second portion in a plan view.

5. The method of claim 1, wherein the depositing of the inorganic insulating film comprises depositing the inorganic insulating film so that the inorganic insulating film does not contact an upper surface of the pad.

6. The method of claim 1, wherein
the ribs define a plurality of openings, the plurality of openings including the opening,
the base substrate comprises a plurality of base panels, the plurality of base panels comprising the base panel, and
each of the openings overlaps each of the base panels in a plan view.

7. The method of claim 6, wherein each of the base panels comprises a display area and a pad portion on the side of the display panel and in which a pad is located; and
the coating layer crosses each of the plurality of openings, and overlaps each of the pad portions of the plurality of base panels in a plan view.

8. The method of claim 1, wherein each of the ribs, the frame, and the coating layer comprises at least one of a metal, a polymer, a carbon fiber reinforced plastic (CFRP), or a ceramic.

9. The method of claim 1, further comprising forming the coating layer through a coating process.

10. The method of claim 1, wherein the base substrate comprises a silicon wafer substrate for manufacturing an OLED on silicon (OLEDoS) display device.

11. The method of claim 1, wherein
the base panel comprises a light-emitting element layer comprising a light-emitting element, and
the depositing of the inorganic insulating film comprises forming an encapsulation layer on the light-emitting element layer so that the encapsulation layer is not in contact with the pad.

12. A mask comprising:
a frame comprising ribs defining openings, the openings each having a first portion and a second portion; and
a coating layer on the frame, and
wherein the coating layer crosses the openings and overlaps the first portion of each of the openings in a plan view.

13. The mask of claim 12, wherein each of the ribs, the frame, and the coating layer comprises at least one of a metal, a polymer, a carbon fiber reinforced plastic (CFRP), or a ceramic.

14. The mask of claim 12, wherein the coating layer does not overlap the second portion of each of the openings in a plan view.

15. The mask of claim 12, wherein the coating layer is formed through a coating process.

16. An electronic device comprising display device comprising:
a substrate having a display area and a non-display area around the display area, the non-display area comprising a pad portion in which a pad is located;
a light-emitting element layer on the substrate and comprising a light-emitting element; and
an encapsulation layer covering the light-emitting element layer,
wherein the encapsulation layer does not overlap the pad portion in a plan view.

17. The electronic device of claim 16, wherein the encapsulation layer is not in contact with the pad.

18. The electronic device of claim 16, wherein the encapsulation layer comprises an inorganic insulating film on the substrate, and
the inorganic insulating film does not contact an upper surface of the pad.

19. The electronic device of claim 18, wherein the electronic device is a head-mounted display (HMD), a virtual reality (VR) device, a mixed reality (MR) device, or an augmented reality (AR) device.

20. The method of claim 1, further comprising assembling the display device into an electronic device, wherein the electronic device is a head-mounted display (HMD), a virtual reality (VR) device, a mixed reality (MR) device, or an augmented reality (AR) device.
